(19) United States
(12) Patent Application Publication
(10) Pub. No.: US 2014/0234760 A1
(43) Pub. Date: Aug. 21, 2014

(54) TRANSLUCENT ELECTROMAGNETIC SHIELD FILM, PRODUCING METHOD THEREFOR AND EMULSIFIER

(71) Applicant: FUJIFILM Corporation, Tokyo (JP)

(72) Inventors: Hirotomo SASAKI, Kanagawa (JP); Ryou NISHIZAKURA, Kanagawa (JP)

(73) Assignee: FUJIFILM Corporation, Tokyo (JP)

(21) Appl. No.: 14/259,583

(22) Filed: Apr. 23, 2014

Related U.S. Application Data
(62) Division of application No. 11/159,218, filed on Jun. 23, 2005.

(30) Foreign Application Priority Data
Jun. 23, 2004 (JP) 2004-184436
Jun. 23, 2004 (JP) 2004-184437

(51) Int. Cl. G03F 7/06; G03F 7/20

(52) U.S. Cl. CPC G03F 7/06; G03F 7/20
USPC 430/9

(57) ABSTRACT

A producing method for a translucent electromagnetic shield film comprising exposing a photosensitive material having an emulsion layer containing a silver salt and a dye on a substrate, then executing a development process to form a metallic silver portion and a light transmitting portion respectively in an exposed area and an unexposed area, and applying a physical development and/or a plating process to the metallic silver portion thereby causing the metallic silver portion to carry a conductive metal. The producing method allows to inexpensively mass produce a translucent electromagnetic shield film without a moiré pattern, having a high EMI shield property and a high transparency at the same time.

### CROSS REFERENCE TO RELATED APPLICATIONS

This application is a divisional of U.S. patent application Ser. No. 11/159,218, filed Jun. 23, 2005, which claims priority to Japanese Patent Application Nos. 2004-184436 and 2004-184437, filed Jun. 23, 2004, the contents of each of which are incorporated herein by reference in their entirety.

### BACKGROUND OF THE INVENTION

1. Field of the Invention

The present invention relates to a producing method for a translucent electromagnetic shield film having transparency and capable of shielding an electromagnetic wave generated from a front face of a display such as a cathode ray tube (CRT), a plasma display panel (PDP), a liquid crystal display, an electroluminescence display (EL) or a field emission display (FED), a microwave oven, an electronic appliance or a printed circuit board, and a translucent electromagnetic shield film obtained by such producing method, also a translucent electromagnetic shield film for a plasma display panel and a plasma display panel having such film. The present invention also relates to a photosensitive silver halide emulsion, a conductive silver film forming material utilizing the same, a silver halide photosensitive material, a conductive silver material and an electrode material.

2. Background Art

With the recent increase in the utilization of various electric facilities and electronic equipment, electromagnetic interferences (EMI) are increasing significantly. Such EMI not only induces erroneous operations and troubles on electronic/electric equipment but also is pointed out to cause troubles on the health of operators of such equipment. It is therefore required, in such electronic/electric equipment, to restrict an electromagnetic emission within a standard or regulated range.

For avoiding EMI, a shielding of the electromagnetic wave is required, and this can obviously be achieved utilizing a property of metal not transmitting the electromagnetic wave. For example there are employed a method of forming a casing with a metal or a highly conductive material, a method of inserting a metal plate between the circuit boards, and a method of covering a cable with a metal foil. However, in CRT or PDP, a transparency for a display is required as the operator has to be able to recognize a character or the like on such display. In the aforementioned methods, the front side of the display generally becomes opaque and such methods are inadequate for a shielding method for the electromagnetic wave.

In particular, the PDP emits a larger amount of electromagnetic wave in comparison with a CRT, and requires a stronger electromagnetic shielding ability. The electromagnetic shielding ability can be represented, in a simple way, by a surface resistivity. For example, in a translucent electromagnetic shield material for a CRT, there is required a surface resistivity of about 300 Ω/sq or less, while, in a translucent electromagnetic shield material for a PDP, a surface resistivity of 2.5 Ω/sq or less is required, and, for a consumer-use plasma television utilizing a PDP, a resistivity of 1.5 Ω/sq or less is strongly desired, more desirably as low as 0.1 Ω/sq or less.

Also the requirement for transparency is about 70% or higher for a CRT and 80% or higher for a PDP, and an even higher transparency is being desired.

In order to meet these requirements, there have been proposed various materials and methods to achieve an electromagnetic shielding property and a transparency at the same time, utilizing a metal mesh having apertures, as will be explained in the following.

### (1) Etched Mesh Formed by Photolithography

There is proposed a method of etching a copper foil by photolithography to form a copper mesh on a transparent substrate (cf. JP-A No. 10-41682). This method, being capable of a fine structuring, provides advantages capable of producing a mesh of a high aperture rate (high transmission), and shielding even a strong electromagnetic emission. It is however associated with a drawback that the mesh has to be manufactured through a number of production steps.

Also because of the use of a copper foil, the obtained mesh is not black but has a copper color, thereby causing a decrease in the image contrast of the display equipment. Also because of the etching process, the crossing point of the mesh pattern becomes wider than the width of the line portion, and an improvement is being desired in relation to the moiré phenomenon.

### (2) Conductive Silver Formation Utilizing Silver Salt

In 1960s, there is proposed a method of forming a conductive thin metallic silver film pattern by a silver salt diffusion transfer process utilizing a silver deposition on a physical development nucleus (for example cf. JP-B No. 42-23746).

Also this principle is applied to various methods of forming a conductive pattern in a simple manner by an exposure and a development with a monochromatic instant slide film (for example cf. Analytical Chemistry, vol. 72, 645(2000)), and WO01/51276, pamphlet P. 10, Example 1 and FIG. 1). Also there is proposed a method of forming a conductive silver film, usable as a display electrode of a plasma display, utilizing the principle of silver salt diffusion transfer process (for example cf. JP-A No. 2000-149773, claims 1 and 2, and page 2, paragraphs 0005 to 0006).

However, it has not been known at all to prepare a conductive metallic silver by such method for shielding the electromagnetic wave emitted from the image display face of the display such as CRT or PDP without hindering the image display.

Also in the methods described in the aforementioned five literatures, specially prepared physical development nuclei are present uniformly in a layer in which the conductive metallic pattern is to be formed, without distinction between an exposed area and an unexposed area. Therefore, in an exposed area where the metallic silver film is not formed, opaque physical development nuclei remain thereby hindering the optical transparency. Particularly in the method of forming the conductive pattern by executing an exposure and a development utilizing a monochromatic instant slide film, metallic silver is generated also in a transparent portion (light transmitting portion) at the electroless silver plating, whereby the deterioration of the transparency becomes more conspicuous. Such drawback is serious in case of use as a translucent electromagnetic shield material for a display such as CRT or PDP.

Another drawback is a difficulty in obtaining a high conductivity. Also there is another drawback that the transparency is deteriorated when a thick silver film is formed in order to obtain a high conductivity. It is therefore not possible, with the aforementioned methods, to obtain a translucent electromagnetic shield material having satisfactory optical transmission and conductivity suitable for shielding an electromagnetic wave emitting from an image display face of an electronic display equipment.

Also in case of obtaining an electroconductivity through the steps of a development, a physical development and a plating utilizing a commercially available negative photographic film instead of the silver salt diffusion transfer process, the resulting film is insufficient, both in the conductivity and the transparency, for use as a translucent electromagnetic shield material for a CRT or a PDP.

As explained above, the prior electromagnetic shield materials and the producing methods therefor have been associated with drawbacks.

On the other hand, an electromagnetic shield plate, constituted of a mesh of a thin metal film formed on a transparent glass or plastic substrate, having an extremely high electromagnetic shielding ability and capable of providing a satisfactory optical transmission, is being recently employed as an electromagnetic shield film for a display panel such as PDP.

However, since such shield plate is very expensive, a reduction in the production cost is strongly desired. Also for the display application, as a high image luminocity is required, an optical transmittance close to 100% is strongly desired for the electromagnetic shield material.

However, an increase in the aperture rate (a proportion of an area without the fine lines constituting the mesh in the entire area) for improving the optical transmittance reduces the conductivity to deteriorate the electromagnetic shielding effect, and it is very difficult in the prior technology to improve the electroconductivity (electromagnetic shield effect) and the optical transmittance at the same time. Also such electromagnetic shield film, being positioned in front of the image display face of the display, causes a moiré pattern.

### SUMMARY OF THE INVENTION

The present invention has been made in consideration of such situation, and an object of the invention is to provide a producing method for a translucent electromagnetic shield film having a high EMI shield ability and a high transparency at the same time without a moiré pattern, the method being capable of easily forming a fine line pattern and also capable of mass producing the translucent electromagnetic shield film inexpensively. Another object of the invention is to provide a translucent electromagnetic shield film obtained by the aforementioned producing method. Still another object of the invention is to provide a translucent electromagnetic shield film for a plasma display panel containing the aforementioned translucent electromagnetic shield film, an optical filter for a plasma display panel, and a plasma display panel. Still another object of the invention is to provide an emulsion and a silver halide photosensitive material capable of simply forming a metallic silver portion having a high conductivity, and also to provide conductive silver material, an electrode material and a wiring material obtainable therefrom.

As a result of intensive investigation for attaining a high EMI shield ability and a high transparency at the same time, the present inventors have found that the aforementioned objects can be attained effectively by a producing method for a translucent electromagnetic shield film and a translucent electromagnetic shield film explained in the following, and have thus made the present invention.

Thus, the objects of the invention can be attained by following producing methods.

(1) A producing method for a translucent electromagnetic shield film comprising exposing a photosensitive material having an emulsion layer containing a silver salt and a protective layer in this order on a substrate, then developing the exposed material to form a metallic silver portion and a light transmitting portion respectively in an exposed area and an unexposed area, and applying a physical development and/or a plating process to the metallic silver portion thereby causing the metallic silver portion to carry a conductive metal.
(2) A producing method for a translucent electromagnetic shield film comprising exposing a photosensitive material having an emulsion layer containing a silver salt and a dye on a substrate, then developing the exposed material to form a metallic silver portion and a light transmitting portion respectively in an exposed area and an unexposed area, and applying a physical development and/or a plating process to the metallic silver portion thereby causing the metallic silver portion to carry a conductive metal.
(3) A producing method for a translucent electromagnetic shield film described in (1) or (2), wherein the translucent electromagnetic shield film after the physical development and/or the plating process has a surface resistivity of 10 Ω/sq or lower and an aperture rate of 85% or higher.
(4) A translucent electromagnetic shield film prepared by a producing method described in any one of (1) to (3).
(5) A translucent electromagnetic shield film for a plasma display panel including a translucent electromagnetic shield film obtained by a producing method described in any one of (1) to (3).
(6) An optical filter for a plasma display panel including a translucent electromagnetic shield film obtained by a producing method described in any one of (1) to (3).
(7) A plasma display panel including a translucent electromagnetic shield film for a plasma display panel described in (5).
(8) A photosensitive silver halide emulsion including at least a silver halide and being capable of forming, by an exposure and a chemical development, a metallic silver portion having a volume resistivity of 1.6-100 μΩcm.
(9) A photosensitive silver halide emulsion described in (8) including at least a silver halide and being capable of forming, by an exposure and a chemical development, a metallic silver portion having a volume resistivity of 1.6-50 μΩcm.
(10) A photosensitive silver halide emulsion described in (8) including at least a silver halide and being capable of forming, by an exposure and a chemical development, a metallic silver portion having a volume resistivity of 1.6-10 μΩcm.
(11) A conductive silver film forming material prepared by coating and drying a photosensitive silver halide emulsion described in any one of (8) to (10).
(12) A silver halide photosensitive material including a silver salt containing layer obtained by coating and drying a photosensitive silver halide emulsion described in any one of (8) to (10) on a substrate.
(13) A conductive silver material prepared by a pattern exposure and a chemical development of the silver halide photosensitive material described in (12).
(14) An electrode material employing a conductive silver material described in (13).
(15) A wiring material employing a conductive silver material described in (13).

### BEST MODE FOR CARRYING OUT THE INVENTION

In the following, there will be given a detailed description of a producing method for a translucent electromagnetic shield film of the present invention and a translucent electromagnetic shield film and the like.

In the present specification, a symbol “−” means a range including numbers in front of and behind such symbol as a lower limit value and an upper limit value.

### <<Producing Method for Translucent Electromagnetic Shield Film>>

A first producing method for a translucent electromagnetic shield film of the invention (hereinafter also simply called “first producing method”) is characterized in exposing a photosensitive material having an emulsion layer containing a silver salt and a protective layer in this order on a substrate, then executing a development process to form a metallic silver portion and a light transmitting portion respectively in an exposed area and an unexposed area, and applying a physical development and/or a plating process to the metallic silver portion thereby causing the metallic silver portion to carry a conductive metal.

A second producing method for a translucent electromagnetic shield film of the invention (hereinafter also simply called “second producing method”) is characterized in exposing a photosensitive material having an emulsion layer containing a silver salt and a dye on a substrate, then executing a development process to form a metallic silver portion and a light transmitting portion respectively in an exposed area and an unexposed area, and applying a physical development and/or a plating process to the metallic silver portion thereby causing the metallic silver portion to carry a conductive metal.

Thus, the first producing method employs a photosensitive material having at least a protective layer on an emulsion layer, and the second producing method employs a photosensitive material containing at least a dye in the emulsion layer. In the following, there will be principally explained matters which are common to the first and second producing methods (these being collectively called “producing method of the invention”), and features of each producing method will be explained in appropriate positions.

### <Photosensitive Material>

### [Substrate]

A substrate for the photosensitive material to be employed in the producing method of the invention can be, for example, a plastic film, a plastic plate or a glass plate.

A raw material for the plastic film or the plastic plate can be, for example, a polyester such as polyethylene terephthalate (PET), or polyethylene naphthalate; a polyolefin such as polyethylene (PE), polypropylene (PP), polystyrene or EVA; a vinylic resin such as polyvinyl chloride, or polyvinylidene chloride; polyether ether ketone (PEEK), polysulfone (PSF), polyethersulfone (PES), polycarbonate (PC), polyamide, polyimide, acrylic resin, or triacetyl cellulose (TAC).

In the invention, the plastic film is preferably a polyethylene terephthalate film in consideration of transparency, heat resistance, easy of handling and cost.

As an electromagnetic shield material for a display is required to have a transparency, the substrate preferably has a high transparency. In such case, the plastic film or the plastic plate preferably has a transmittance in the entire visible region of 70-100%, more preferably 85-100% and particularly preferably 90-100%. Also in the invention, the plastic film or the plastic plate may be colored to an extent not hindering the objects of the invention.

In the invention, the plastic film or the plastic plate may be employed in a single layer or as a multi-layered film by combining two or more layers.

In case of employing a glass plate as the substrate in the invention, it is not particularly restricted in its type, but, for an electromagnetic shield film for a display, there is preferably employed a tempered glass having a tempered layer on the surface. A tempered glass has a higher possibility of breakage prevention in comparison with an untempered glass. Also a tempered glass obtained by an air cooling method gives, even in case of an eventual breakage, small fragments with unsharp edges, and is preferable for safety.

### [Protective Layer]

The photosensitive material employed in the first producing method is provided with a protective layer on an emulsion layer to be explained later. In the invention, a “protective layer” means a layer formed by a binder such as gelatin or a polymer, and is formed on the emulsion layer having photosensitivity, for the purpose of preventing scratches and improving mechanical characteristics. The protective layer has a thickness of 0.02-20 μm, preferably 0.1-10 μm and further preferably 0.3-3 μm. A coating method for the protective layer is not particularly restricted, and a known coating method can be appropriately selected.

The photosensitive material to be employed in the first producing method, namely the photosensitive material having a protective layer may contain, in the emulsion layer, a substance similar to a dye containing in the photosensitive material employed in the second producing method.

### [Emulsion Layer]

The photosensitive material to be employed in the producing method of the invention has, on the substrate, an emulsion layer containing a silver salt as a photosensor (silver salt containing layer). The emulsion layer in the invention may contain, in addition to the silver salt, a dye, a binder, a solvent and the like if necessary.

### <Dye>

The photosensitive material to be employed in the second producing method contains a dye at least in the emulsion layer. Such dye is included in the emulsion layer as a filter dye, or for various purposes such as prevention of irradiation. The dye may include a solid dispersed dye. Dyes preferably employed in the invention include those represented by general formulas FA, FA1, FA2 and FA3 in JP-A No. 9-179243, more specifically compounds F1-F34 described in therein. Also there can be advantageously employed compounds (II-2)-(II-24) described in JP-A No. 7-152112, those (III-5)-(III-18) described in JP-A No. 7-152112 and those (IV-2)-(IV-7) described in JP-A No. 7-152112.

Also the dyes employable in the invention include, as a dye dispersed in solid fine particles to be discolored at the developing or fixing process, a cyanine dye, a pyrilium dye and an aminium dye described in JP-A No. 3-138640. Also as a dye not discolored at the processing, there can be employed a cyanine dye having a carboxyl group described in JP-A No. 9-96891, a cyanine dye not containing an acidic group described in JP-A No. 8-245902 and a lake cyanine dye described in JP-A No. 8-333519, a cyanine dye described in JP-A No. 1-266536, a holopolar cyanine dye described in JP-A No. 3-136038, a pyrilium dye described in JP-A No. 62-299959, a polymer cyanine dye described in JP-A No. 7-253639, a solid particle dispersion of an oxonol dye described in JP-A No. 2-282244, light scattering particles described in JP-A No. 63-131135, a Yb³⁺ compound described in JP-A No. 9-5913 and an ITO powder described in JP-A No. 7-113072. There can also be employed dyes represented by general formulas F1 and F2 described in JP-A No. 9-179243, more specifically compounds F35-F112 therein.

Also a water-soluble dye may be contained as the aforementioned dye. Such water-soluble dye can be an oxonol dye, a benzylidene dye, a merocyanine dye, a cyanine dye or an azo dye. Among these, an oxonol dye, a hemioxonol dye or a benzylidene is useful in the invention. Specific examples of the water-soluble dye employable in the invention include those described in BP Nos. 584,609 and 1,177,429, JP-A Nos. 48-85130, 49-99620, 49-114420, 52-20822, 59-154439, and 59-208548, U.S. Pat. Nos. 2,274,782, 2,533,472, 2,956,879, 3,148,187, 3,177,078, 3,247,127, 3,540,887, 3,575,704, 3,653,905 and 3,718,427.

In the emulsion layer, the dye preferably has a content of 0.01-10 mass % to the total solid in consideration of an irradiation preventing effect and a reduction in the sensitivity by an increase in the content, more preferably 0.1-5 mass %.

### <Silver Salt>

A silver salt to be employed in the invention can be an inorganic silver salt such as silver halide, or an organic silver salt such as silver acetate. In the invention, there is preferably employed a silver halide having an excellent property as a photosensor.

The silver halide advantageously employed in the invention will be explained.

In the invention, silver halide is preferably employed for a function as a photosensor, and technologies of a silver salt photographic film, a photographic paper, a lithographic film and an emulsion mask for a photomask relating to silver halide are applicable also in the invention.

A halogen element contained in the silver halide may be any of chlorine, bromine, iodine and fluorine or a combination thereof. For example, a silver halide principally formed by AgCl, AgBr or AgI is employed preferably, and a silver halide principally formed by AgBr or AgCl is employed more preferably. Also silver chlorobromide, silver iodochlorobromide or silver iodobromide can be employed preferably. More preferably there is employed silver chlorobromide, silver bromide, silver iodochlorobromide or silver iodobromide, and most preferably silver chlorobromide or silver iodochlorobromide containing silver chloride by 50 mol. % or more.

A term “silver halide principally formed by AgBr (silver bromide)” means silver halide in which bromine ions represent a molar ratio of 50% or higher in the composition of silver halide. Such silver halide particle principally formed by AgBr may contain iodine ions or chlorine ions in addition to bromine ions.

Silver halide is in solid grains, and, in consideration of an image quality of a patterned metallic silver layer formed after the exposure and the development process, preferably has an average grain size of 0.1-1000 nm (1 μm) in a sphere-corresponding diameter, more preferably 0.1-100 nm and further preferably 1-50 nm.

A sphere-corresponding diameter of silver halide grain means a diameter of a spherical particle of a same volume.

The silver halide grain is not particularly restricted in its shape, and may have various shapes such as spherical, cubic, planar (hexagonal flat plate, triangular flat plate or tetragonal flat plate), octahedral or tetradecahedral, preferably cubic or tetradecahedral.

In the silver halide grain, an interior and a surface part may be formed by a uniform phase or of different phases. Also it may include a localized layer of a different halogen composition, in the interior or on the surface of the grain.

A silver halide emulsion, used as an emulsion layer coating liquid in the invention, can be prepared by methods described for example in P. Glafkides, Chimie et Physique Photographique (published by Paul Montel, 1967), G. F. Dufin, Photographic Emulsion Chemistry (The Focal Press, 1966) and V. L. Zelikman et al., Making and Coating Photographic Emulsion (The Focal Press, 1964).

More specifically, the silver halide emulsion may be prepared by an acidic method or a neutral method, and, a reaction between a soluble silver salt and a soluble halogen salt may be executed by a one-side mixing method, a simultaneous mixing method or a combination thereof.

Also the grain formation may be achieved by a method of forming grains in the presence of silver ions in excess (so-called inverse mixing method). Also as a form of the simultaneous mixing method, there may be employed a method of maintaining a constant pAg in the liquid phase in which silver halide is formed, namely so-called controlled double jet method.

It is also preferable to execute grain formation utilizing so-called silver halide solvent such as ammonia, a thioether, or a tetra-substituted thiourea. Such method more preferably employs a tetra-substituted thiourea, as described in JP-A Nos. 53-82408 and 55-77737. A preferred thiourea compound can be tetramethyl thiourea or 1,3-dimethyl-2-imidazolidinethione. An amount of the silver halide solvent is variable depending on a type of the compound, a desired grain size and a halogen composition, but is preferably 10⁻⁵ to 10⁻² moles per 1 mole of silver halide.

A grain forming process utilizing the controlled double jet method and the silver halide solvent can easily form a silver halide emulsion with a regular crystal shape and a narrow particle size distribution and is preferably employed in the invention.

Also for obtaining a uniform grain size, it is preferable to rapidly grow silver within an extent not exceeding a critical saturation, for example by a method of varying an addition rate of silver nitrate or alkali halide according to a grain growth speed as described in BP No. 1,535,016, JP-B Nos. 48-36890 and 52-16364, or a method of varying a concentration of an aqueous solution as described in JBP No. 4,242,445 and JP-A No. 55-158124. The silver halide emulsion employed for forming the emulsion layer of the invention is preferably a single-dispersion emulsion, having a variation factor represented by {(standard deviation of grain size)/(average grain size)}×100 of 20% or less, more preferably 15% or less and most preferably 10% or less.

The silver halide emulsion employed in the present invention may also be a mixture of plural silver halide emulsions of different grain sizes.

The silver halide emulsion to be employed in the invention may contain a metal belonging to a group VIII or VIIB of the periodic table. Particularly for attaining a high contrast and a low fog level, it is preferable to include a rhodium compound, an iridium compound, a ruthenium compound, an iron compound, an osmium compound or a rhenium compound. Such compound can be a compound having various ligands, which can be, for example, a cyan ion, a halogen ion, a thiocyanate ion, a nitrosyl ion, water or a hydroxide ion, and which can also be, in addition to such pseudo halogen, ammonia, or an organic molecule for example an amine (such as methylamine or ethylenediamine), a heterocyclic compound (such as imidazole, thiazole, 5-methylthiazole or mercaptoimidazole), urea or thiourea.

Also for attaining a high sensitivity, there is advantageously employed a doping with a hexacyano metal complex such as K₄[Fe(CN)₆], K₄[Ru(CN)₆], or K₃[Cr(CN)₆].

The rhodium compound can be a water-soluble rhodium compound, of which examples include a rhodium (III) halide, a hexachlororhodium (III) complex salt, a pentachloro acorhodium complex salt, a tetrachloro diagnorhodium complex salt, a hexabromorhodium (III) complex salt, a hexamine rhodium (III) complex salt, a trioxalatorhodium (III) complex salt, and K₃Rh₂Br₉. Such rhodium compound is employed by dissolving in water or a suitable solvent, and a common method for stabilizing the solution of the rhodium compound, namely a method of adding an aqueous solution of a hydrogen halide (such as hydrochloric acid, hydrobromic acid or hydrofluoric acid) or an alkali halide (such as KCl, NaCl, KBr or NaBr), can be utilized. It is also possible, instead of employing a water-soluble rhodium compound, to add and dissolve, at the preparation of silver halide, other silver halide grains doped in advance with rhodium.

The iridium compound can be a hexachloroiridium complex salt such as K₂IrCl₆ or K₃IrCl₆, a hexabromoiridium complex salt, a hexaammineiridium complex salt, or a pentachloronitrisil iridium complex salt.

The ruthenium compound can be hexachlororuthenium, pentachloro nitrosyl ruthenium, or K₄[Ru(CN)₆].

The iron compound can be potassium hexacyanoferrate (II), or ferrous thiocyanate.

Rhenium, ruthenium or osmium is added in the form of a water-soluble complex salt as described in JP-A Nos. 63-2042, 1-285941, 2-20852 and 2-20855, and there is particularly preferably employed a 6-coordination complex represented by a following formula:

[ML₆]⁻ⁿ

wherein M represents Ru, Re or Os; and n represents 0, 1, 2, 3 or 4.

In this case, a counter ion is not important and can for example be ammonium of an alkali metal ion. Also a preferable ligand can be a halide ligand, a cyanide ligand, an oxycyanide ligand, a nitrosyl ligand, or a thionitrosyl ligand. In the following specific examples of the complex employable in the invention are shown, but the invention is not limited to such examples:

[ReCl₆]⁻³, [ReBr₆]⁻³, [ReCl₅(NO)]⁻², [Re(NS)Br₅]⁻², [Re(NO)(CN)₅]⁻², [Re(O)₂(CN)₄]⁻³, [RuCl₆]⁻³, [RuCl₄(H₂O)₂]⁻¹, [RuCl₅(NO)]⁻², [RuBr₅(NS)]⁻², [Ru(CO)₃Cl₃]⁻², [Ru(CO)Cl₅]⁻², [Ru(CO)Br₅]⁻², [OsCl₆]⁻³, [OsCl₅(NO)]⁻², [Os(NO)(CN)₅]⁻², [Os(NS)Br₅]⁻², [Os(CN₆)]⁻⁴ and [Os(O)₂(CN)₅]⁻⁴.

Such compound is preferably added with an amount of 10⁻¹⁰ to 10⁻² mol/mol·Ag per 1 mole of silver halide, more preferably 10⁻⁹ to 10⁻³ mol/mol·Ag.

Also in the invention, silver halide containing a Pd (II) ion and/or a Pd metal can be employed advantageously. Pd may be uniformly distributed within a silver halide grain, but is preferably included in the vicinity of a surface layer of the silver halide grain. The expression that Pd is “included in the vicinity of a surface layer of the silver halide grain” means that the silver halide grain has a layer with a higher palladium content than in other layers, within a depth of 50 nm from the surface of the silver halide grain. Such silver halide grain can be prepared by adding Pd in the course of formation of the silver halide grain, and it is preferable to add Pd after silver ions and halogen ions are added by more than 50% of the total addition amounts. Also Pd (II) ions may be advantageously made present in the surface layer of silver halide by adding Pd (II) ions in a post-ripening stage.

Such Pd-containing silver halide grains increases a speed of a physical development or an electroless plating to improve the production efficiency of the desired electromagnetic shield material, thereby contributing to a reduction of the production cost. Pd is well known and employed as a catalyst for an electroless plating, and, in the present invention, it is possible to localize Pd in the surface layer of the silver halide grains, thereby saving extremely expensive Pd.

In the invention, Pd ions and/or Pd metal preferably has a content, in the silver halide, of 10⁻⁴ to 0.5 mole/mol·Ag with respect to a number of moles of silver in silver halide, more preferably 0.01 to 0.3 mole/mol·Ag.

The Pd compound to be employed can be, for example, PdCl₄ or Na₂PdCl₄.

In the invention, in order to further improve the sensitivity as the photosensor, a chemical sensitization practiced in photographic emulsion may also be adopted. As the chemical sensitization, there can be utilized a chalcogen sensitization such as sulfur sensitization, selenium sensitization or tellurium sensitization, a precious metal sensitization such as gold sensitization, or a reduction sensitization. Such sensitization may be employed singly or in combination. In case of employing a combination of chemical sensitizations, for example a combination of sulfur sensitization and gold sensitization, a combination of sulfur sensitization, selenium sensitization and gold sensitization, or a combination of sulfur sensitization, tellurium sensitization and gold sensitization is preferable.

The sulfur sensitization is normally executed by adding a sulfur sensitizer and agitating the emulsion for a predetermined time at a high temperature of 40° C. or higher. The sulfur sensitizer can be a known sulfur compound including a sulfur compound contained in gelatin and various sulfur compounds, such as a thiosulfate salt, a thiourea, a thiazole or a rhodanine. A preferred sulfur compound is a thiosulfate salt or a thiourea compound. An amount of the sulfur sensitizer is variable depending on various conditions such as a pH and a temperature at the chemical ripening, and a grain size of the silver halide, and is preferably 10⁻⁷ to 10⁻² moles per 1 mole of silver halide, more preferably 10⁻⁵ to 10⁻³ moles.

A selenium sensitizer to be employed in the selenium sensitization can be a known selenium compound. The selenium sensitization is normally executed by adding an unstable and/or non-unstable selenium compound and agitating the emulsion for a predetermined time at a high temperature of 40° C. or higher. The unstable selenium compound can be those described in JP-B Nos. 44-15748 and 43-13489 and JP-A Nos. 4-109240 and 4-324855. Particularly preferably compounds represented by general formulas (VIII) and (IX) in JP-A No. 4-324855 can be employed.

A tellurium sensitizer employed in the tellurium sensitization is a compound capable of generating silver telluride, which is assumed to constitute a sensitizing nucleus, on the surface or in the interior of silver halide grains. A silver telluride generating speed in the silver halide emulsion can be tested by a method described in JP-A No. 5-313284. Specific examples of the compound include those described in U.S. Pat. Nos. 1,623,499, 3,320,069, and 3,772,031, BP Nos. 235,211, 1,121,496, 1,295,462 and 1,396,696, Canadian Patent No. 800,958, JP-A Nos. 4-204640, 4-271341, 4-333043 and 5-303157, J. Chem. Soc. Chem. Commun., 635 (1980), ibid., 1102(1979), ibid., 645(1979), J. Chem Soc. Perkin. Trans., 1, 2191(1980), S. Patai, The Chemistry of Organic Selenium and Tellurium Compounds, Vol. 1 (1986), and ibid., Vol. 2 (1987). In particular, compounds represented by the general formulas (II), (III) and (IV) in JP-A No. 5-313284.

An amount of the selenium sensitizer or the tellurium sensitizer employable in the invention is variable depending on the silver halide grains to be used and the condition of chemical ripening, but is generally 10⁻⁸ to 10⁻² moles per 1 mole of silver halide, preferably 10⁻⁷ to 10⁻³ moles. The chemical sensitization in the invention is not particularly restricted in the conditions, but is usually conducted with a pH of 5-8, a pAg of 6-11, preferably 7-10 and a temperature of 40-95° C., preferably 45-85° C.

Also as the precious metal sensitizer, there can be employed gold, platinum, palladium or iridium, among which gold sensitization is particularly preferable. A gold sensitizer to be employed in the gold sensitization can be chloroautic acid, potassium chloroaurate, potassium aurithiocyanate, gold sulfide, thioglucose gold (I) or thiomannose gold (I), and can be employed in an amount of 10⁻⁷ to 10⁻² moles per 1 mole of silver halide. In the silver halide emulsion to be employed in the invention, a cadmium salt, a sulfite salt, a lead salt or a thallium salt may be included at the process of silver halide grain formation or of physical ripening.

Also a reduction sensitization may be utilized in the invention. A reduction sensitizer can be a stannous salt, an amine, formamidinesulfinic acid or a silane compound. In the silver halide emulsion, a thiosulfonic acid compound may be added by a method described in EP No. 293917. The silver halide emulsion to be employed in the preparation of the photosensitive material of the invention may be a single emulsion or a combination of two or more emulsions (different for example in an average grain size, a halogen composition, a crystalline state, a condition of chemical sensitization or a sensitivity). For obtaining a high contrast, it is preferable, as described in JP-A No. 6-324426, to coat an emulsion of a higher sensitivity in a position closer to the substrate.

Now there will be explained a hydrazine derivative employable in the invention. In the invention, a hydrazine derivative can be employed as a nucleation agent. In the invention, there can be advantageously employed a compound of a general formula (I) in JP-A No. 7-287335, and more specifically compounds represented by I-1 to 1-53 therein. Preferred examples of the hydrazine derivative include following: compounds represented by (chemical formula 1) in JP-B No. 6-77138, more specifically those described in pages 3 and 4 therein; compounds represented by a general formula (I) in JP-B No. 6-93082, more specifically those 1-38 described in pages 8-18 therein; compounds represented by general formulas (4), (5) and (6) in JP-A No. 6-230497, more specifically those 4-1 to 4-10 in pages 25 and 26, those 5-1 to 5-42 in pages 28 to 36, and those 6-1 to 6-7 in pages 39 and 40; compounds represented by a general formulas (1) and (2) in JP-a No. 6-289520, more specifically those 1-1) to 1-17 and 2-1) described in pages 5-7 therein; compounds represented by (chemical formula 2) and (chemical formula 3) in JP-A No. 6-313936, more specifically those described in pages 6-19 therein; compounds represented by (chemical formula 1) in JP-A No. 6-313951, more specifically those described in pages 3-5 therein; compounds represented by a general formula (I) in JP-A No. 7-5610, more specifically those I-1 to 1-38 described in pages 5-10 therein; compounds represented by a general formula (II) in JP-A No. 7-77783, more specifically those II-1 to 11-102 described in pages 10-27 therein; compounds represented by a general formula (H) and a general formula (Ha) in JP-A No. 7-104426, more specifically those H-1 to H-44 described in pages 8-15 therein; compounds described in JP-A No. 9-222082, having, in the vicinity of a hydrazine group, a nonionic group capable of forming an intramolecular hydrogen bond with an anionic group or a hydrogen of hydrazine, as represented by general formulas (A), (B), (C), (D), (E) and (F) and more specifically those N-1 to N-30 described therein; and compounds represented by a general formula (1) in JP-A No. 9-22082, more specifically those D-1 to D-55 described therein.

A hydrazine nucleating agent utilizing a hydrazine derivative and employable in the invention can be used by dissolving in a suitable water-miscible organic solvent for example an alcohol (such as methanol, ethanol, propanol, or a fluorinated alcohol), a ketone (such as acetone or methyl ethyl ketone), dimethylformamide, dimethylsulfoxide, or methyl cellosolve. Also it may be used as an emulsion, utilizing a well known emulsification method, by dissolving, utilizing an oil such as dibutyl phthalate, tricresyl phosphate, glyceryl triacetate or diethyl phthalate and an auxiliary solvent such as ethyl acetate or cyclohexanone, and mechanically forming into an emulsion. Also it may be used as a dispersion, utilizing so-called solid dispersion method, by dispersing a powder of a hydrazine derivative in water by a ball mill, a colloid mill or an ultrasonic wave.

The hydrazine nucleating agent may be added in the emulsion layer or in any other hydrophilic colloid layer provided at a side of the substrate of the photosensitive material of the invention, on which the emulsion layer is provided, but is preferably added in the silver halide emulsion layer or a hydrophilic colloid layer adjacent thereto. In the invention, an amount of the nucleating agent is preferably 1×10⁻⁶ to 1×10⁻² moles with respect to 1 mole silver halide, more preferably 1×10⁻⁵ to 5×10⁻³ moles and most preferably 2×10⁻⁵ to 5×10⁻³ moles.

Also the photosensitive material to be employed in the producing method of the invention may utilize a nucleation promoter. Such nucleation promoter can be an amine derivative, an onium salt, a disulfide derivative or a hydroxymethyl derivative. Examples thereof include followings: compound described in JP-A No. 7-77783, page 48, lines 2-37, more specifically compounds A-1 to A-37 described in pages 49-58; compounds represented by (chemical formula 21), (chemical formula 22) and (chemical formula 23) in JP-A No. 7-84331, more specifically those described in pages 6-8 therein; compounds represented by general formulas [Na] and [Nb] in JP-A No. 7-104426, more specifically those Na-1 to Na-22 and Nb-1 to Nb-12 in pages 16-20 therein; compounds represented by general formulas (1), (2), (3), (4), (5), (6) and (7) in JP-A No. 8-272023, more specifically those 1-1 to 1-19, 2-1 to 2-22, 3-1 to 3-36, 4-1 to 4-5, 5-1 to 5-41, 6-1 to 6-58 and 7-1 to 7-38 therein; and nucleation promoters described in JP-A No. 9-297377.

The nucleation promoter can be used by dissolving in a suitable water-miscible organic solvent for example an alcohol (such as methanol, ethanol, propanol, or a fluorinated alcohol), a ketone (such as acetone or methyl ethyl ketone), dimethylformamide, dimethylsulfoxide, or methyl cellosolve. Also it may be used as an emulsion, utilizing a well known emulsification method, by dissolving, utilizing an oil such as dibutyl phthalate, tricresyl phosphate, glyceryl triacetate or diethyl phthalate and an auxiliary solvent such as ethyl acetate or cyclohexanone, and mechanically forming into an emulsion. Also it may be used as a dispersion, utilizing so-called solid dispersion method, by dispersing a powder of a hydrazine derivative in water by a ball mill, a colloid mill or an ultrasonic wave.

The nucleation promoter may be added in the emulsion layer or in any other hydrophilic colloid layer provided at a side of the substrate of the photosensitive material of the invention, on which the emulsion layer is provided, but is preferably added in the silver halide emulsion layer or a hydrophilic colloid layer adjacent thereto. In the invention, an amount of the nucleation promoter is preferably 1×10⁻⁶ to 2×10⁻² moles with respect to 1 mole silver halide, more preferably 1×10⁻⁵ to 2×10⁻² moles and most preferably 2×10⁻⁵ to 1×10⁻² moles.

The emulsion layer in the invention may be spectrally sensitized with a sensitizing dye to a blue light, a green light and a red or infrared light of a relatively long wavelength. As the sensitizing dye, there can be employed a cyanine dye, a merocyanine dye, a complex cyanine dye, a complex merocyanine dye, a holoholer cyanine dye, a styryl dye, a hemicyanine dye, an oxonol dye or a hemioxonol dye. Such sensitizing dyes are described for example in Research Disclosure Item 176431V-A (December 1978, p. 23), ibid., Item 1831X (August 1979, p. 437) and literatures cited therein.

For such sensitizing dye, a sensitizing dye having a spectral sensitivity matching the spectral characteristics of the light source at the exposure can be advantageously selected. For example, A) for an argon laser light source, there can be advantageously selected compounds (I)-1 to (I)-8 described in JP-A No. 60-162247, those I-1 to 1-28 described in JP-A No. 2-48653, those I-1 to 1-13 described in JP-A No. 4-330434, those of Examples 1-14 described in U.S. Pat. No. 2,161,331 and those 1-7 described in GP No. 936,071.

B) For a helium-neon laser light source, there can be advantageously selected compounds 1-1 to 1-38 described in JP-A No. 54-18726, those I-1 to 1-35 described in JP-A No. 6-75322 and those I-1 to 1-34 described in JP-A No. 7-287338.

C) For an LED light sourced, there can be advantageously selected dyes 1 to 20 described in JP-B No. 55-39818, compounds I-1 to 1-37 described in JP-A No. 62-284343 and those I-1 to 1-34 described in JP-A No. 7-287338.

D) For a semiconductor laser light source, there can be advantageously selected compounds I-1 to 1-12 described in JP-A No. 59-191032, those I-1 to 1-22 described in JP-A No. 60-80841, those I-1 to 1-29 described in JP-A No. 4-335342 and those I-1 to 1-18 described in JP-A No. 59-192242.

E) For a tungsten or xenon light source employed for a lithographic camera or the like, there can be advantageously selected compound (1) to (19) represented by a general formula [I] in JP-A No. 55-45015, those I-1 to 1-97 described in JP-A No. 9-160185, those 4-A to 4-S, 5-A to 5-Q and 6-A to 6-T described in JP-A No. 6-242547.

Such sensitizing dye may be employed singly or in a combination. A combination of sensitizing dyes is often utilized for the purpose of super sensitization. Also, a dye not having a spectral sensitizing effect by itself or a substance which does not substantially absorb the visible light and which shows a super sensitizing effect may be included, together with the sensitizing dye, in the emulsion layer. Useful sensitizing dyes, combinations of dyes showing super sensitization and substances showing super sensitization are described in Research Disclosure, vol. 176, 17643 (December 1978), p. 23 IV-J, and JP-B Nos. 49-25500 and 43-4933, and JP-A Nos. 59-19032 and 59-192242.

As explained above, the sensitizing dye may be employed in a combination of two or more kinds. For addition into the emulsion layer, the sensitizing dye may be directly dispersed in the silver halide emulsion, or may be added to the emulsion by dissolving in a single solvent such as water, methanol, ethanol, propanol, acetone, methyl cellosolve, 2,2,3,3-tetrafluoropropanol, 2,2,2-trifluoroethanol, 3-methoxy-1-propanol, 3-methoxy-1-butanol, 1-methoxy-2-propanol or N,N-dimethylformamide, or a mixed solvent thereof. There can also be utilized a method, as disclosed in U.S. Pat. No. 3,469,987, of dissolving a dye in a volatile solvent, then dispersing the solution in water or a hydrophilic colloid and adding such dispersion into the emulsion; a method, as disclosed in JP-B Nos. 44-23389, 44-27555 and 57-22091, of dissolving a dye in an acid, and adding obtained solution to the emulsion or causing an acid or a base to be present in the solution and adding it to the emulsion; a method, as disclosed in U.S. Pat. Nos. 3,822,135 and 4,006,025, of adding an aqueous solution or a colloid dispersion formed in the presence of a surfactant, to the emulsion; a method, as disclosed in JP-A Nos. 53-102733 and 58-105141, of directly dispersing a dye into the hydrophilic colloid and adding such dispersion to the emulsion; or a method, as disclosed in JP-A No. 51-74624, of dissolving a dye with a compound showing a red shift and adding the obtained solution into the emulsion. Also an ultrasonic wave may be applied to the solution.

The aforementioned dye may be added to the silver halide emulsion at any timing in the course of preparation of the emulsion. The addition may be executed in any timing or any step before the emulsion is coated, for example, as disclosed in U.S. Pat. Nos. 2,735,766, 3,628,960, 4,183,756 and 4,225,666 and JP-A Nos. 58-184142 and 60-196749, in a silver halide grain forming step and/or a period before a desalting, in a desalting step and/or a period after a desalting and before the start of a chemical ripening, or as disclosed in JP-A No. 58-113920, a period immediately before or during a chemical ripening, or in a period after the chemical ripening and before the coating. It is also possible, as disclosed in U.S. Pat. No. 4,225,666 or JP-A No. 58-7629, to add a same compound either singly or in combination with different compounds in divided manner, for example in a grain forming step and in or after a chemical ripening step, or before or in the chemical ripening and after the completion thereof, and the compound to be added in divided manner and the combination of the compounds may be changed in such additions.

An amount of the sensitizing dye is variable depending on a shape, a size and a halogen composition of the silver halide grains, a method and a level of chemical sensitization and a type of an antifoggant, but is preferably within a range of 4×10⁻⁶ to 8×10⁻³ moles per 1 mole of silver halide. For example, in case the silver halide grains have a size of 0.2 to 1.3 μm, there is preferred an addition of 2×10⁻⁷ to 3.5×10⁻⁶ moles per 1 m² of the surface area of the silver halide grains, more preferably 6.5×10⁻⁷ to 2.0×10⁻⁶ moles.

The emulsion layer or the protective layer of the photosensitive material to be employed in the producing method of the invention may contain various surfactants for various purposes such as an auxiliary coating agent, an antistatic agent, and improvements in lubrication, emulsification, anti-sticking and photographic properties (such as acceleration of development, increase of contrast, sensitization). Such surfactant can be a nonionic surfactant such as saponin (steroid), an alkylene oxide derivative (such as polyethylene glycol, a polyethylene glycol/polypropylene glycol condensate, a polyethylene glycol alkyl aryl ether, a polyethylene glycol ester, a polyethylene glycol sorbitan ester, a polyalkylene glycol alkylamine or alkylamide, or a polyethylene oxide addition product of silicone), a glycidol derivative (such as alkenylsuccinate polyglyceride, or alkylphenol polyglyceride), a fatty acid ester of a polyhydric alcohol, or an alkyl ester of a sugar; an anionic surfactant having a carboxyl group, a sulfo group, a phospho group, a sulfate ester group or a phosphate ester group such as an alkylcarboxylate salt, an alkylsulfonate salt, an alkylbenzenesulfonate salt, an alkylnaphthalenesulfonate salt, an alkylsulfate ester, an alkylphosphate ester, an N-acyl-N-alkyltaurine, a sulfosuccinate ester, a sulfoalkylpolyoxyethylene alkylphenyl ether, or a polyoxyethylene alkylphosphate ester; an amphoteric surfactant such as an amino acid, an aminoalkylsulfonic acid, an aminoalkyl sulfate or phosphate ester, an alkylbetain or an aminoxide; or a cationic surfactant such as an alkylamine salt, an aliphatic or aromatic quaternary ammonium salt, a heterocyclic quaternary ammonium salt such as pyridinium or imidazolium salt, or an aliphatic or heterocyclic phosphonium or sulfonium salt.

Various additives in the photosensitive material to be employed in the producing method of the invention are not particularly restricted, and those described for example in the following literatures can be employed advantageously:

a polyhydroxybenzene compound described in JP-A No. 3-39948, page 10, lower right column, line 11 to page 12, lower left column, line 5, more specifically those (III)-1 to 25 described therein;

a compound substantially free from an absorption maximum in the visible region, represented by a general formula (I) in JP-A No. 1-118832, more specifically those I-1 to 1-26 described therein;

an antifoggant described in JP-A No. 2-103536, page 17, lower right column, line 19 to page 18, upper right column, line 4;

a polymer latex described in JP-A No. 2-103536, page 18, lower left column, line 12 to page 18, lower left column, line 20;

a polymer latex having an active methylene group represented by a general formula (I) in JP-A No. 9-179228, more specifically compounds I-1 to 1-16 described therein;

a polymer latex having a core-shell structure described in JP-A No. 9-179228, more specifically compounds P-1 to P-55 described therein;

an acidic polymer latex described in JP-A No. 7-104413, page 14, left column, line 1 to page 14, right column, line 30, more specifically compounds II-1) to 11-9) described on page 15 thereof;

a matting agent, a lubricant and a plasticizer described in JP-A No. 2-103536, page 19, upper left column, line 15 to page 19, upper right column, line 15;

a hardening agent described in JP-A No. 2-103536, page 18, upper right column, line 5 to page 18, upper right column, line 17;

a compound having an acid group described in JP-A No. 2-103536, page 18, lower right column, line 6 to page 19, upper left column, line 1;

a conductive substance described in JP-A No. 2-18542, page 2, lower left column, line 13 to page 3, upper right column, line 7, more specifically a metal oxide described in ibid., page 2, lower right column, line 2 to page 2, lower right column, line 10, and conductive polymers P-1 to P-7 described therein;

a redox compound capable of being oxidized to release a development inhibitor described in JP-A No. 5-274816, preferably those represented by general formulas (R−1), (R-2) and (R-3), more specifically those R-1 to R-68 described therein; and

a binder described in JP-A No. 2-18542, page 3, lower right column, line 1 to line 20.

An emulsion usable for forming the emulsion layer of the photosensitive material to be employed in the producing method of the invention can preferably be, for example an emulsion for a color negative film described in examples of JP-A Nos. 11-305396, 2000-321698, 13-281815 and 2002-72429; an emulsion for a color reversal film described in JP-A No. 2002-214731; an emulsion for a color photographic paper described in JP-A No. 2002-107865; an emulsion for a photomask photosensitive material described in examples of JP-A Nos. 2002-72421, 2000-105441; and an emulsion for a graphic arts photosensitive material described in examples of JP-A No. 2001-209151.

### <Binder>

The emulsion layer of the photosensitive material to be employed in the producing method of the invention can employ a binder for the purposes of uniformly dispersing the silver salt grains and assisting an adhesion between the emulsion layer and the substrate. Such binder in the invention can be a water-insoluble binder or a water-soluble binder, but a water-soluble binder is preferred.

Such binder can be, for example, gelatin, polyvinyl alcohol (PVA), polyvinylpyrrolidone (PVP), a polysaccharide such as starch, cellulose and a derivative thereof, polyethylene oxide, a polysaccharide, a polyvinylamine, chitosan, polylysine, polyacrylic acid, polyalginic acid, polyhyaluronic acid, or carboxycellulose. These materials have a neutral, anionic or cationic property depending on the ionic property of the functional group.

An amount of the binder contained in the emulsion layer of the invention is not particularly restricted, and can be suitably selected within a range of meeting the dispersibility and the adhesion. The amount of the binder in the emulsion layer in a Ag/binder volume ratio within a range of 1/4-100, more preferably 1/3-10, further preferably 1/2-2 and most preferably 1/1-2. The binder present in the emulsion layer in a Ag/binder volume ratio of 1/4 or higher facilitates mutual contact of the metal particles in the physical development and/or plating process thereby advantageously obtaining a high conductivity.

### <Solvent>

A solvent to be employed in forming the emulsion layer is not particularly restricted, and can be, for example, water, an organic solvent (for example an alcohol such as methanol, a ketone such as acetone, an amide such as formamide, a sulfoxide such as dimethyl sulfoxide, an ester such as ethyl acetate, or an ether), an ionic liquid or a mixture thereof.

In the emulsion layer of the invention, the solvent is employed in an amount within a range of 30-90 mass % with respect to the total mass of the silver salt, the binder and the like contained in the emulsion layer, preferably within a range of 50-80 mass %.

Additives to be employed in the photosensitive material of the invention are not particularly restricted, and those described for example in the following literatures can be employed advantageously.

### 1) Nucleation Promoter

A nucleation promoter can be a compound of general formulas (I), (II), (III), (IV), (V) and (VI) described in JP-A No. 6-82943, or those represented by general formulas (II-m) to (II-p) in JP-A No. 2-103536, page 9, upper right column, line 13 to page 16, upper left column, line 10 and in compound examples II-1 to 11-22 therein and described in JP-A No. 1-179939.

### 2) Spectral Sensitizing Dye

A spectral sensitizing dye can be that described in JP-A No. 2-12236, page 8, lower left column, line 13 to lower right column, line 4, JP-A No. 2-103536, page 16, lower right column, line 3 to page 17, lower left column, line 20, and those described in JP-A Nos. 1-112235, 2-124560, 3-7928 and 5-11389.

### 3) Surfactant

A surfactant can be that described in JP-A No. 2-12236, page 9, upper right column, line 7 to lower right column, line 7, and JP-A No. 2-18542, page 2, lower left column, line 13 to page 4, lower right column, line 18.

### 4) Antifoggant

An antifoggant can be a thiosulfinic acid compound described in JP-A No. 2-103536, page 17, lower right column, line 19 to page 18, upper right column, line 4, also in page 18, lower right column lines 1-5, and in JP-A No. 1-237538.

### 5) Polymer Latex

A polymer latex can be that described in JP-A No. 2-103536, page 18, lower left column, lines 12-20.

### 6) Compound Having Acid Group

A compound having an acid group can be a compound described in JP-A No. 2-103536, page 18, lower right column, line 6 to page 19, upper left column, line 1.

### 7) Matting Agent, Lubricant

A matting agent can be a compound described in JP-A No. 2-103536, page 19, upper left column, line 15 to page 19, upper right column, line 15.

### 8) Hardening Agent

A hardening agent can be a compound described in JP-A No. 2-103536, page 18, upper right column, lines 5 to 17.

### 9) Dye

A dye can be a solid dye described in JP-A No. 2-103536, page 17, lower right column, lines 1 to 18, and in JP-A Nos. 2-294638 and 5-11382.

### 10) Binder

A binder can be that described in JP-A No. 2-18542, page 3, lower right column, lines 1-20.

### 11) Black Pepper Spot Preventing Agent

A black pepper spot preventing agent is a compound for suppressing a spot-shaped developed silver in an unexposed area, and can be a compound described for example in U.S. Pat. No. 4,956,257 and JP-A No. 1-118832.

### 12) Redox Compound

A redox compound can be a compound represented by a general formula (I) in JP-A No. 2-301743 (particularly compound examples 1-50), a compound of general formulas (R-1), (R-2) and (R-3) or, compound examples 0.1-75 described in JP-A No. 3-174143, page 3 to page 20, and that described in JP-A Nos. 5-257239 and 4-278939.

### 13) Monomethine Compound

A monomethine compound can be a compound of a general formula (II) in JP-A No. 2-287532 (particularly compound examples II-1 to 11-26).

### 14) Dihydroxybenzene

A dihydroxybenzene can be a compound described in JP-A No. 3-39948, page 11, upper left column to page 12, lower left column, and in EP 452772A.

(Preferable Emulsion)

An emulsion particularly preferably employed in the invention is a photosensitive silver halide emulsion containing at least a silver halide and capable, by an exposure and a chemical development, of forming a metallic silver portion of a volume resistivity of 1.6-100 μΩcm (hereinafter called photosensitive silver halide emulsion of the invention). More specifically, a conductive silver material having a metallic silver portion, on a substrate, of a volume resistivity of 1.6-100 μΩcm can be obtained by coating and drying the photosensitive silver halide emulsion of the invention to forma silver salt-containing layer, and executing a pattern exposure and a chemical development on such silver salt-containing layer. Therefore a conductive silver film-forming material, constituted of a silver salt-containing layer formed by coating and drying the photosensitive silver halide emulsion of the invention, or a silver halide photosensitive material having such conductive silver film-forming material on a substrate is capable, by an exposure and a chemical development, of providing a metallic silver portion of a volume resistivity of 1.6-100 μΩcm.

The conductive silver material has a wide concept including any conductive silver portion formed on a substrate, in which the translucent electromagnetic shield film of the invention is also included. Also the metallic silver portion formed on the substrate may be a conductive metallic silver image.

The photosensitive silver halide emulsion of the invention is more preferably capable, by an exposure and a chemical development, of forming a metallic silver portion of a volume resistivity of 1.6-50 μΩcm, and further preferably capable, by an exposure and a chemical development, of forming a metallic silver portion of a volume resistivity of 1.6-10 μΩcm. The photosensitive silver halide emulsion of the invention can be obtained for example by increasing the volume ratio of Ag to the binder to the aforementioned range.

The photosensitive silver halide emulsion of the invention allows to obtain a metallic silver portion of a high conductivity in a simple manner. The conductive silver material obtained with the photosensitive silver halide emulsion of the invention, having a volume resistivity of 1.6-10 μΩcm and a high electromagnetic shielding ability, is extremely useful as an electromagnetic shield film (particularly a translucent electromagnetic shield film for a plasma display panel and the like) and an electrode material such as a bus electrode of a display equipment.

### [Exposure]

In the producing method of the invention, an exposure is given to the emulsion layer provided on the substrate. The exposure can be executed with an electromagnetic radiation. The electromagnetic radiation can be, for example, a visible light, a light such as ultraviolet light, or a radiation such as X-ray. Also the exposure can be executed with a light source having a wavelength distribution, or a light source of a specified wavelength.

The light source can be, for example, a scanning exposure utilizing a cathode ray tube (CRT). A cathode ray tube exposure apparatus is simpler, more compact and less expensive in comparison with an apparatus utilizing a laser. It also enables easy adjustments of an optical axis and colors. A cathode ray tube employed for image exposure utilizes various light emitting substances showing a light emission in a necessary spectral region. For example a red light emitting substance, a green light emitting substance or a blue light emitting substance is employed either singly or in a mixture of two or more kinds. The spectral region is not limited to the aforementioned red, green and blue regions, and a light emitting substance, emitting light in a yellow, orange, purple or infrared region, can also be employed. In particular, there is frequently employed a cathode ray tube emitting a white light by mixing these light emitting substances. An ultraviolet lamp is also advantageously employed, and g-line or i-line of a mercury lamp is also utilized.

In the invention, the exposure can be executed with various laser beams. The exposure in the invention can be preferably executed by a scanning exposure method utilizing monochromatic high-density light of a gas laser, a light-emitting diode, a semiconductor laser, of a second harmonic generator (SHG) formed by a combination of a semiconductor laser or a solid-state laser employing a semiconductor laser as an exciting light source and a non-linear optical crystal. The exposure in the invention can also utilize a KrF excimer laser, an ArF excimer laser or an F2 laser. For obtaining a compact and inexpensive system, the exposure is preferably executed with a semiconductor laser or a second harmonic generator (SHG) formed by a combination of a semiconductor laser or a solid-state laser and a non-linear optical crystal. In particular, for designing a compact, inexpensive, long-life and highly stable apparatus, the exposure is preferably executed with a semiconductor laser.

Preferred examples of the laser light source include a blue semiconductor laser of a wavelength of 430-460 nm (published by Nichia Chemical Co. at 48th United Meeting of Applied Physics (March, 2001); a green light laser of about 530 nm which is obtained by a wavelength conversion of a light of a semiconductor laser (oscillation wavelength of about 1060 nm) by a LiNbO₃ SHG crystal having a waveguide-type inverted domain structure; and a red semiconductor laser of a wavelength of about 685 nm (Hitachi type: HL6738MG); or a red semiconductor laser of a wavelength of about 650 nm (Hitachi type: HL6501MG).

A pattern exposure of the emulsion layer can be executed by a planar exposure utilizing a photomask, or by a scanning exposure with a laser beam. A refractive exposure employing a lens or a reflective exposure employing a mirror may be employed, and there can be utilized a contact exposure, a proximity exposure, a reduction projection exposure or a reflective projection exposure.

### [Developing Process]

In the invention, a development process is executed after the exposure of the emulsion layer. The development process can be executed with an ordinary developing technology employed for example in a silver halide photographic film or paper, a lithographic film or an emulsion mask for photomask. A developing solution is not particularly restricted, and can be a PQ developer, a MQ developer or an MAA developer. In a commercial product, a developing solution or a developing solution in a kit, such as CN-16, CR-56, CP45X, FD-3, or Papitol manufactured by Fuji Photo Film Co., or C-41, E-6, RA-4, D-19 or D-72 manufactured by Eastman Kodak Co. Also a lithographic developer can be employed. In case of employing a lithographic developer, it is preferable to use polyethylene glycol.

The lithographic developing solution can be D85 manufactured by Eastman Kodak Co. In the invention, the exposure and the developing process described above form a metallic silver portion, preferably a patterned metallic silver portion in an exposed area, and a light transmitting portion to be explained later in an unexposed area.

In the producing method of the invention, the developing solution may employ a developing agent of dihydroxybenzene type. Such dihydroxybenzene developing agent can be hydroquinone, chlorohydroquinone, isopropylhydroquinone, methylhydroquinone, or a hydroquinonemonosulfonate salt, among which hydroquinone is particularly preferable. An auxiliary developing agent showing a super additivity with the dihydroxybenzene developing agent includes a 1-phenyl-3-pyrrazolidone and a p-aminophenol. The developing solution employed in the producing method of the invention preferably employs a combination of a dihydroxybenzene developing agent and a 1-phenyl-3-pyrrazolidone or a combination of a dihydroxybenzene developing agent and a p-aminophenol.

A developing agent that can be combined with 1-phenyl-3-pyrrazolidone or a derivative thereof can be 1-phenyl-3-pyrrazolidone, 1-phenyl-4,4-dimethyl-3-pyrrazolidone or 1-phenyl-4-methyl-4-hydroxymethyl-3-pyrrazolidone.

The auxiliary developing agent of p-aminophenol type can be N-methyl-p-aminophenol, p-aminophenol, N-(β-hydroxyethyl)-p-aminophenol or N-(4-hydroxyphenyl)glycine, among which N-methyl-p-aminophenol is preferred. The dihydroxybenzene developing agent is usually employed in an amount of 0.05-0.8 mol/liter, but is preferably employed, in the invention, in an amount of 0.23 mol/liter or higher, more preferably in an amount within a range of 0.23-0.6 mol/liter. Also in case of employing a combination of a dihydroxybenzene and a 1-phenyl-3-pyrrazolidone or a p-aminophenol, it is preferable to employ the former in an amount of 0.23-0.6 mol/liter, more preferably 0.23-0.5 mol/liter, and the latter in an amount of 0.06 mol/liter or less, more preferably 0.03-0.003 mol/liter.

In the invention, each of a development starter solution and a developer replenisher solution preferably has a property of “showing a pH increase of 0.5 or less when 0.1 moles of sodium hydroxide are added to 1 liter of the solution”. Such property of the development starter solution or the developer replenisher solution to be used can be confirmed by regulating the development starter solution or the developer replenisher solution to be tested at a pH value of 10.5, then adding 0.1 moles of sodium hydroxide to 1 liter of such solution, measuring the pH value of the solution and identifying that a pH increase is 0.5 or less. The producing method of the invention preferably employs a development starter solution and a developer replenisher solution showing a pH increase of 0.4 or less in the above-described test.

For providing the development starter solution or the developer replenisher solution with the aforementioned property, a method utilizing a buffer is preferably utilized. The buffer can be a carbonate salt, boric acid described in JP-A No. 62-186259, a sugar (such as saccharose) described in JP-A No. 60-93433, an oxime (such as acetoxime), a phenol (such as 5-sulfosalicylic acid), or a tertiary phosphate salt (such as a sodium salt or a potassium salt), preferably a carbonate salt or boric acid. The buffer (particularly carbonate salt) is preferably employed in an amount of 0.25 mol/liter or higher, particularly preferably 0.25-1.5 mol/liter. In the invention, the development starter solution preferably a pH value of 9.0-11.0, particularly preferably 9.5-10.7. Also the developer replenisher solution and the developing solution in a developing tank in a continuous processing have a pH value within such range. An alkali to be employed for pH adjustment can be an ordinary water-soluble inorganic alkali metal salt (such as sodium hydroxide, potassium hydroxide, sodium carbonate or potassium carbonate).

In the producing method of the invention, in processing a photosensitive material of 1 m², a content of the developer replenisher solution in the developing solution is 323 ml or less, preferably 323-30 ml and particularly preferably 225-50 ml. The developer replenisher solution may have a composition same as that of the development starter solution, or may have a higher concentration than that of the development starter solution, on a component to be consumed in the development.

The developing solution for a developing process of the photosensitive material of the invention (hereinafter “development starter solution” and “developer replenisher solution” may be collectively referred to as “developing solution”) may contain an ordinary additive (such as a stabilizer or a chelating agent). Such stabilizer can be a sulfite salt such as sodium sulfite, potassium sulfite, lithium sulfite, ammonium sulfite, sodium bisulfite, potassium metabisulfite, or sodium formaldehyde bisulfite. Such sulfite salt is preferably employed in an amount of 0.20 mol/liter or higher, more preferably 0.3 mol/liter or higher, but is employed 1.2 mol/liter or less as an excessive addition causes a silver stain in the developing solution. A particularly preferred range is 0.35-0.7 mol/liter. Also a stabilizer for a dihydroxybenzene developing agent, a small amount of an ascorbic acid derivative may be employed in combination with the sulfite salt. The ascorbic acid derivative includes ascorbic acid, erysorbic acid which is a steric isomer thereof and an alkali metal salt thereof (such as sodium salt or potassium salt). As the ascorbic acid derivative, sodium erysorbate is preferably employed for the material cost. The ascorbic acid derivative is preferably employed in an amount within a range of 0.03-0.12 in a molar ratio to the dihydroxybenzene developing agent, particularly preferably within a range of 0.05-0.10. Incase of employing an ascorbic acid derivative as the stabilizer, the developing solution preferably does not include a boron compound.

Other additives employable in the developing solution include a development inhibitor such as sodium bromide or potassium bromide; an organic solvent such as ethylene glycol, diethylene glycol, triethylene glycol or dimethylformamide; a development promoter for example an alkanolamine such as diethanolamine or triethanolamine, imidazole or a derivative thereof; and a mercapto compound, an indazole compound, a benzotriazole compound or a benzoimidazole compound as an antifoggant or a black pepper spot preventing agent. Specific examples of the benzoimidazole compound include 5-nitroindazole, 5-p-nitrobenzoylaminoindazole, 1-methyl-5-nitroindazole, 6-nitroindazole, 3-methyl-5-nitroindazole, 5-nitrobenzimidazole, 2-isopropyl-5-nitrobenzimidazole, 5-nitrobenzotriazole, sodium 4-[(2-mercapto-1,3,4-thiadiazol-2-yl)thio]butanesulfonate, 5-amino-1,3,4-thiadiazole-2-thiol, methylbenzotriazole, 5-methylbenzotriazole and 2-mercaptobenzotriazole. Such benzoimidazole compound is employed in a content of 0.01-10 mmol per 1 liter of the developing solution, more preferably 0.1-2 mmol.

The developing solution may further contain an organic or inorganic chelating agent. The inorganic chelating agent can be sodium tetrapolyphosphate or sodium hexametaphosphate. Also the organic chelating agent can principally be an organic carboxylic acid, an aminopolycarboxylic acid, an organic phosphonic acid, an aminophosphonic acid or an organic phosphonocarboxylic acid.

The organic carboxylic acid can be acrylic acid, oxalic acid, malonic acid, succinic acid, glutaric acid, adipic acid, pimelic acid, succinic acid, azelaic acid, sebacic acid, nonanedicarboxylic acid, decanedicarboxylic acid, undecanedicarboxylic acid, maleic acid, itaconic acid, malic acid, citric acid, or tartaric acid, but such examples are not exhaustive.

The aminopolycarboxylic acid can be iminodiacetic acid, nitrilotriacetic acid, nitrilotripropionic acid, ethylenediamine monohydroxyethyltriacetic acid, ethylenediamine tetraacetic acid, glycol ether tetraacetic acid, 1,2-diaminopropane tetraacetic acid, diethylenetriamine pentaacetic acid, triethylenetetramine hexaacetic acid, 1,3-diamino-2-propanol tetraacetic acid, glycol ether diamine tetraacetic acid, or a compound described in JP-A Nos. 52-25632, 55-67747, and 57-102624, and JP-B No. 53-40900.

The organic phosphonic acid can be a hydroxyalkylidene diphosphonic acid described in U.S. Pat. Nos. 3,214,454 and 3,794,591 and GP-A No. 2227639, or a compound described in Research Disclosure, vol. 181, Item 18170 (May 1979).

The aminophosphonic acid can be aminotris (methylenephosphonic acid), ethylenediamine tetramethylenephosphonic acid, or aminotrimethylene phosphonic acid, or a compound described in Research Disclosure No. 18170, JP-A Nos. 57-208554, 54-61125, 55-29883 and 56-97347.

The phosphonocarboxylic acid can be a compound described in JP-A Nos. 52-102726, 53-42730, 54-121127, 55-4024, 55-4025, 55-126241, 55-65955, and 55-65956, and Research Disclosure No. 18170. Such chelating agent may be employed in the form of an alkali metal salt or an ammonium salt.

Such chelating agent is preferably added in an amount of 1×10⁻⁴ to 1×10⁻¹ moles per 1 liter of the developing solution, more preferably 1×10⁻³ to 1×10⁻² moles.

The developing solution may further contain, as a silver stain preventing agent, a compound described in JP-A Nos. 56-24347 and 56-46585, JP-B No. 62-2849 and JP-A No. 4-362942. Also as an auxiliary solvent, a compound described in JP-A No. 61-267759 may be employed. The developing solution may further contain a color toning agent, a surfactant, a defoamer, a hardening agent and the like, if necessary. A developing temperature and a developing time are mutually related and are determined in relation to a total process time, but the developing temperature is generally preferably about 20 to 50° C., more preferably 25-45° C. Also the developing time is preferably 5 seconds to 2 minutes, more preferably 7 to 90 seconds.

For the purposes of saving a transportation cost, a packing cost and a space of the developing solution, there is also preferred an embodiment of concentrating the developing solution and diluting it at the use. For concentrating the developing solution, it is effective to employ potassium salts in the salts contained in the developing solution.

The development process in the invention can include a fixing process executing for the purpose of eliminating the silver salt in an unexposed area thereby achieving stabilization. The fixing process in the invention can be executed with an ordinary fixing technology employed for example in a silver halide photographic film or paper, a lithographic film or an emulsion mask for photomask.

The fixing solution employed in the fixing step preferably contains following components.

The fixing solution preferably contains sodium thiosulfate or ammonium thiosulfate, and, if necessary tartaric acid, citric acid, gluconic acid, boric acid, iminodiacetic acid, 5-sulfosalicylic acid, glucoheptanoic acid, tiron, ethylenediamine tetraacetic acid, diethylenetriamine pentaacetic acid, nitrotriacetic acid or a salt thereof. From the standpoint of recent environmental consideration, boric acid is preferably absent. In the fixing solution to be employed in the invention, a fixing agent can be sodium thiosulfate or ammonium thiosulfate, and ammonium thiosulfate is preferred in consideration of the fixing speed, but sodium thiosulfate may also be employed from the standpoint of the recent environmental consideration. An amount of such known fixing agent is suitably variable, but is generally about 0.1-2 mol/liter, preferably 0.2-1.5 mol/liter. The fixing solution may contain, if desired, a hardening agent (such as a water-soluble aluminum compound), a stabilizer (such as a sulfite salt, or a bisulfite salt), a pH buffer (such as acetic acid), a pH regulating agent (such as ammonia or sulfuric acid), a chelating agent, a surfactant, a humidifying agent, a fixing promoter and the like.

The surfactant can be an anionic surfactant such as a sulfate compound or a sulfonated compound, a polyethylene-based surfactant, or an amphoteric surfactant described in JP-A No. 57-6740. Also in the fixing solution, a known defoaming agent may be added.

The humidifying agent can be, for example, an alkanolamine or an alkylene glycol. Also the fixing promoter can be a thiourea derivative described in JP-B Nos. 45-35754, 58-122535 and 58-122536; an alcohol having a triple bond in the molecule; a thioether compound described in U.S. Pat. No. 4,126,459; a mesoion compound described in JP-A No. 4-229860; or a compound described in JP-A No. 2-44355. The pH buffer can be an organic acid such as acetic acid, malic acid, succinic acid, tartaric acid, citric acid, oxalic acid, maleic acid, glycolic acid, or adipic acid; or an inorganic buffer such as boric acid, a phosphate salt or a sulfite salt. The pH buffer is preferably acetic acid, tartaric acid or a sulfite salt. The pH buffer is employed for the purpose of preventing a pH increase in the fixing solution by a carry-over of the developing solution, preferably in an amount of 0.01-1.0 mol/liter, more preferably 0.02-0.6 mol/liter. The fixing solution preferably has a pH value of 4.0-6.5, particularly preferably 4.5-6.0. Also as a dye dissolution promoter, a compound described in JP-A No. 64-4739 may be employed.

The hardening agent to be employed in the fixing solution of the invention can be a water-soluble aluminum salt or a chromium salt. The hardening agent is preferably a water-soluble aluminum salt, such as aluminum chloride, aluminum sulfate or potassium alum, and is preferably added in an mount of 0.01-0.2 mol/liter, more preferably 0.03-0.08 mol/liter.

In the fixing step, a fixing temperature is preferably about 20-50° C., more preferably 25-45° C., and a fixing time is preferably 5 seconds to 1 minute, more preferably 7-50 seconds. A replenishing amount of the fixing solution is preferably 600 ml/m² to the processed amount of the photosensitive material, more preferably 500 ml/m² or less and particularly preferably 300 ml/m² or less.

The photosensitive material subjected to the developing and fixing processes is preferably subjected to a rinsing process or a stabilization process. In the rinsing process or the stabilization process, the rinsing is normally executed with a water amount of 20 liters or less per 1 m² of the photosensitive material, with a replenishing amount of 3 liters or less (including 0, namely rinsing in a standing water bath). It is therefore possible to achieve a water saving but also to dispense with a piping in an automatic processor. For reducing the replenishing amount of rinsing water, there is already known a multi-step (2- or 3-step) countercurrent system. In case such multi-step countercurrent system is employed in the producing method of the invention, the photosensitive material after the fixing step is processed in succession in a proper direction, namely toward a processing solution less contaminated with the fixing solution, whereby a more efficient rinsing can be achieved. Also in case of executing the rinsing operation with a small amount of water, there is preferably provided a rinsing tank with a squeeze roller or a crossover roller as described in JP-A Nos. 63-18350 and 62-287252. Also in order to alleviate a pollution which may arise in the rinsing with a small amount of water, there may be combined an addition of various oxidants or a filtration with a filter. Also in such method, an overflowing liquid from a rinsing bath or a stabilizing bath, resulting from a replenishment of the rinsing bath or the stabilizing bath with water including antimold means, or a part of such overflowing liquid may be utilized as a processing solution having a fixing ability in a preceding process step, as described in JP-A No. 60-235133. Also a water-soluble surfactant or a defoaming agent may be added in order to prevent a bubble pattern which tends to be generated in the rising with a small amount of water and/or a transfer of a processing component from the squeeze roller to the processed film.

Also in the rinsing process or the stabilization process, a dye adsorbent described in JP-A No. 63-163456 may be provided in the rinsing bath, in order to prevent a stain by a dye dissolved from the photosensitive material. Also in the stabilizing process succeeding to the rinsing process, a bath containing a compound described in JP-A Nos. 2-201357, 2-132435, 1-102553 and 46-44446 may be employed as a final bath for the photosensitive material. In such case, it is possible to add, if necessary, an ammonium compound, a metal compound such as of Bi or Al, a fluorescent whitening agent, a chelating agent, a film pH regulating agent, a hardening agent, an antiseptic, an antimold agent, an alkanolamine or a surfactant. The water employed in the rinsing process or the stabilization process can be tap water, or preferably deionized water or water sterilized with a halogen, an ultraviolet sterilizing lamp or an oxidant (such as ozone, hydrogen peroxide or a perchlorate salt). There can also be employed rinsing water containing a compound described in JP-A Nos. 4-39652 and 5-241309. The rinsing process or the stabilization process can preferably employ a bath temperature of 0-50° C. and a time of 5 seconds to 2 minutes.

The processing solution such as the developing solution or the fixing solution to be employed in the invention is preferably stored in a packaging material of a low oxygen permeability, described in JP-A No. 61-73147. Also for reducing a replenishing amount, a contact area of the processing tank with the air is preferably made smaller to avoid evaporation of the solution and oxidation by the air. An automatic processor of a roller conveying type is described for example in U.S. Pat. Nos. 3,025,779 and 3,545,971, and will be simply referred to as a roller conveying processor in the present specification. The roller conveying processor is preferably constituted of four steps of development, fixing, rinsing and drying, and, also in the present invention, such four steps are most preferably adopted, though another step (such as stopping step) will not be excluded. Also the four steps may employ a stabilizing step instead of the rinsing step.

In each of the aforementioned steps, components of the developing solution or the fixing solution may be supplied as a solid by eliminating water, and may be dissolved at use in a predetermined amount of water to form a developing solution or a fixing solution. The processing material of such form is called a solid processing material. The solid processing material is utilized in the form of a powder, a tablet, granules, a block or a paste. A preferred form of the processing material is a form described in JP-A No. 61-259921 or a tablet. Such table can be produced by an ordinary method described for example in JP-A Nos. 51-61837, 54-155038 and 52-88025, and BP No. 1,213,808. Also the granules can be produced by an ordinary method described for example in JP-A Nos. 2-109042, 2-109043, 3-39735 and 3-39739. Also the processing material of powder form can be produced by an ordinary method described for example in JP-A No. 54-133332, BP Nos. 725,892 and 729,862 and GP No. 3,733,861.

The solid processing material preferably has a bulk density of 0.5-6.0 g/cm³ in consideration solubility, more preferably 1.0-5.0 g/cm³.

For preparing the solid processing material, there can be employed a method of placing reactive substances in such a layered manner that at least two mutually reactive granular substances, in the substances constituting the processing material, constitute layers separated by at least an intermediate separating layer of a substance inert to the reactive substances, then employing a bag capable of vacuum packing as a packaging material and evacuating and sealing the bag. “Inert” means that the substances in mutual contact do not react in an ordinary state in the package nor cause a significant reaction. The inactive substance may be inert to the two mutually reactive substances or may be inert in the intended use of the two mutually reactive substances. Also the inert substance is a substance to be employed simultaneously with the two reactive substances. For example, in the developing solution, since hydroquinone and sodium hydroxide react in a direct contact, sodium sulfite or the like may be employed as a separating layer between hydroquinone and sodium hydroxide in the vacuum package, thereby enabling a prolonged storage. Also hydroquinone or the like may be formed in briquettes to reduce the contact area with sodium hydroxide, thereby improving a storage property and enabling use in a mixture. A packaging material for such vacuum package can be a bag formed from an inert plastic film or a laminate of a plastic material and a metal foil.

A mass of metallic silver contained in an exposed area after the development process is preferably 50 mass % or higher with respect to the mass of silver contained in such exposed area prior to the exposure, more preferably 80 mass % or higher. A mass of metallic silver contained in an exposed area of 50 mass % or higher with respect to the mass of silver contained in such exposed area prior to the exposure allows to provide a high electroconductivity.

A gradation after the development process of the invention is not particularly restricted, but is preferably higher than 4.0. A gradation higher than 4.0 after the development process allows to increase the conductivity in the conductive metal portion while maintaining a high transparency in the light transmitting portion. A gradation higher than 4.0 can be obtained, for example, by a doping with rhodium ions or iridium ions as described above.

### [Physical Development and Plating Process]

In the invention, in order to provide a metallic silver portion, formed by the exposure and the development process, with an electroconductivity, a physical development and/or a plating process is conducted for causing the metallic silver portion to carry conductive metal particles. In the invention, the conductive metal particles can be carried on the metallic silver portion by either of the physical development and the plating process, but such carrying of the conductive metal particles on the metallic silver portion may also be achieved by combining the physical development and the plating process. A metallic silver portion, subjected to the physical development and/or the plating process is called a “conductive metal portion”.

A “physical development” in the invention means to reduce a metal ion such as a silver ion with a reducing agent to precipitate a metal particle on a nucleus of a metal or a metal compound. Such physical development is utilizing in an instant monochromatic film, an instant slide film or a lithographic film, and such technology can be utilized in the present invention.

The physical development may be executed simultaneously with the development process after the exposure, or separately after the development process.

In the invention, a plating process may be an electroless plating (chemical reduction plating or substitution plating) and/or an electrolytic plating. The electroless plating in the invention can be executed with a known electroless plating technology, such as that utilized for example in a printing wiring board, and is preferably an electroless copper plating.

Chemical species contained in an electroless copper plating solution include, for example, copper sulfate or copper chloride, a reducing agent such as formalin or glyoxylic acid, a copper ligand such as EDTA or triethanolamine, and additives for bath stabilization and for improving smoothness of a plated film such as polyethylene glycol, a ferrocyanate salt or bipyridine.

An electrolytic copper plating bath can be a copper sulfate bath or a copper pyrophosphate bath.

The plating process in the invention can be executed with a mild plating rate, or with a high-speed plating rate of 5 μm/hr or higher. In the plating process, for the purpose of improving the stability of the plating solution, there can be employed various additives for example a ligand such as EDTA.

### [Oxidation Process]

In the invention, a metallic silver portion after the development process and a conductive metal portion formed by the physical development and/or the plating process are preferably subjected to an oxidation process. The oxidation process can eliminate a metal eventually slightly deposited in a light transmitting portion, thereby obtaining a transparency of approximately 100% in the light transmitting portion.

The oxidation process can be executed by a known process utilizing various oxidants, such as process with Fe (III) ions. As described above, the oxidation process can be executed after the exposure and the development process of the emulsion layer or after the physical development or the plating process, executed after the development process and after the physical development or the plating process.

In the invention, it is furthermore possible to treat the metallic silver portion after the exposure and the development process, with a Pd-containing solution. Pd can be a divalent palladium ion or metallic Pd. Such treatment can accelerate the electroless plating or the physical development.

### [Conductive Metal Portion]

In the following a conductive metal portion in the invention will be explained.

In the invention, the conductive metal portion is formed by subjecting a metallic silver portion, formed by the exposure and the development process, to a physical development or a plating process, thereby causing the metallic silver portion to carry conductive metal particles.

The conductive metal particles to be carried on the metal portion can be silver particles, or particles of a metal such as copper, aluminum, nickel, iron, gold, cobalt, tin, stainless steel, tungsten, chromium, titanium, palladium, platinum, manganese, zinc, or rhodium, or an alloy thereof. In consideration of conductivity and cost, the conductive metal particles are preferably those of copper, aluminum or nickel. Also for providing a magnetic shielding property, paramagnetic metal particles are preferably employed as the conductive metal particles.

In order to increase a contrast of the conductive metal portion and to avoid a fading by an oxidation thereof in time, the conductive metal particles contained in the conductive metal portion are preferably copper particles, more preferably those of which at least a surface is subjected to a blackening process. The blackening process can be executed by a method utilized in the field of a printed wiring board, for example by a treatment for 2 minutes at 95° C. in an aqueous solution of sodium chlorite (31 g/l), sodium hydroxide (15 g/l) and trisodium phosphate (12 g/l).

The conductive metal portion preferably contains silver by 50 mass % or higher with respect to the entire mass of the metal contained in such conductive metal portion, more preferably 60 mass % or higher. Silver contained by 50 mass % or higher allows to reduce a time required in the physical development and/or the plating process, to improve the productivity and to reduced the cost.

In case copper and palladium are employed as the conductive metal particles constituting the conductive metal portion, a total mass of silver, copper and palladium is preferably 80 mass % or higher of the total mass of the metal contained in the conductive metal portion, more preferably 90 mass % or higher.

The conductive metal portion of the invention can provide a satisfactory electroconductivity, because of the carrying of the conductive metal particles. Consequently the translucent electromagnetic shield film (conductive metal portion) of the invention preferably has a surface resistivity of 10 Ω/sq or less, more preferably 2.5 Ω/sq or less, further preferably 1.5 Ω/sq or less and most preferably 0.1 Ω/sq or less.

The conductive metal portion in the invention, in an application for a translucent electromagnetic shield material, preferably has a geometrical shape formed by a combination of a triangular shape such as an equilateral triangle, an isosceles triangle, or a right-angled triangle, a quadrilateral such as a square, a rectangle, a rhombus, a parallelogram, or a trapezoid, a regular (n)-polygon such as a regular hexagon or a regular octagon, a circle, an oval or a star-shape, and more preferably a mesh constituted of such geometrical shapes. A triangular shape is most effective for the EMI shielding property, but, in consideration of the visible light transmittance, a regular (n)-polygon with a larger number n is advantageous as it provides a larger aperture rate for a same line width thereby increasing the visible light transmittance.

In an application as a conductive wiring material, the conductive metal portion is not particularly restricted in the shape, and can be selected in an arbitrary shape according to the purpose.

In an application for a translucent electromagnetic shield material, the conductive metal portion has a line width preferably of 20 μm or less and a line gap of 50 μm or more. The conductive metal portion may have a portion with a line width larger than 20 μm in certain purpose such as grounding. Also for the purpose of not conspicuous on an image, the conductive metal portion preferably has a line width less than 15 μm, more preferably less than 10 μm and most preferably less than 7 μm.

The conductive metal portion in the invention preferably has an aperture rate of 85% or higher in consideration of the visible light transmittance, more preferably 90% or higher and most preferably 95% or higher. An “aperture rate” means a ratio of a portion outside the fine line constituting the mesh in the entire area, and, for example, a square lattice mesh of a line width of 10 μm and a pitch of 200 μm has an aperture rate of 90%. The aperture rate of the metallic silver portion in the invention is not particularly restricted in an upper limit, but is preferably 98% or less in consideration of a relationship between the surface resistivity and the line width.

### [Light Transmitting Portion]

In the invention, a light transmitting portion means a portion having transparency, other than the conductive metal portion in the translucent electromagnetic shield film.

In the invention, a “transmittance of the light transmitting portion” means a transmittance indicated by an average transmittance within a wavelength region of 380-780 nm, excluding contributions of an absorption and a reflection of the substrate, and is represented by (transmittance of transparent portion of translucent electromagnetic shield material)/(transmittance of substrate)×100(%). The light transmitting portion preferably has a transmittance of 90% or higher, more preferably 95% or higher, further preferably 97% or higher and most preferably 99% or higher.

The light transmitting portion in the invention is preferably substantially free from physical developing nuclei in order to improve the transmittance. In the invention, in contrast to the prior silver complex salt diffusion transfer process, it is unnecessary to dissolve an unexposed silver halide, to convert it into a soluble silver complex and to diffuse it, the light transmitting portion is substantially free from physical development nuclei.

“Substantially free from physical development nuclei” means that a presence rate of the physical development nuclei in the light transmitting portion is within a range of 0-5%.

In the invention, the light transmitting portion is formed together with the metallic silver portion by an exposure and a development process of the emulsion layer. The light transmitting portion is preferably subjected, for the purpose of improving the transmittance, to the aforementioned oxidation process after the development process and also after the physical development or the plating process.

### [Layer Structure of Translucent Electromagnetic Shield Film]

In the translucent electromagnetic shield film of the invention, the substrate preferably has a thickness of 5-200 and more preferably 30-150 μm. A thickness within the range of 5-200 μm provides a desired transmittance for the visible light and enables an easy handling.

The metallic silver portion, provided on the substrate before the physical development and/or the plating process, has a thickness which can be suitably determined according to a coating thickness of a coating liquid for a silver salt-containing layer, to be coated on the substrate. A thickness of the metallic silver portion is preferably 30 or less, more preferably 20 μm or less, further preferably 0.01-9 μm and most preferably 0.05-5 μm. The metallic silver portion is preferably provided in a patterned shape. Also the metallic silver portion may be constituted of a single layer or may have a multi-layered structure of two or more layers. In case the metallic silver portion has a patterned shape and a multi-layered structure of two or more layers, such layers may be provided with different photosensitivities so as to be sensitive to different wavelengths. Thus, exposures with different exposing wavelengths allow to form different patterns in such layers, and a translucent electromagnetic shield film including thus formed patterned metallic silver portions of a multi-layered structure can be utilized as a high-density printed circuit board.

In an application for an electromagnetic shield material for a display, the conductive metal portion preferably has an as small thickness as possible for increasing a viewing angle of the display. Also in an application for a conductive wiring material, a thinner film is required for achieving a higher density. Because of these requirements, the layer of the conductive metal carried on the conductive metal portion preferably has a thickness less than 9 μm, more preferably 0.1 μm or larger but less than 5 μm and further preferably 0.1 μm or larger but less than 3 μm.

In the present invention, since it is possible to form a metallic silver portion of a desired thickness by controlling the coating thickness of the emulsion layer and to arbitrarily control the layer of the conductive metal particles by the physical development and/or the plating plate, even a translucent electromagnetic shield film of a thickness less than 5 μm, preferably less than 3 μm, can be formed in a simple manner.

In contrast to a prior etching process in which a large portion of the metal thin film has to be etched off and discarded, the present invention, being capable of forming a pattern containing a conductive metal of a necessary amount only on the substrate, can only utilize the metal of a necessary minimum amount, thereby attaining advantages of reductions in the production cost and in the amount of discarded metal.

[Functional Film Other than Electromagnetic Shield]

In the invention, another functional layer having another functionality may be provided if necessary. Such functional layer may have different specifications according to each application. For example in an electromagnetic shield material for a display, there may be provided an antireflective layer with an antireflective function by a regulation in a refractive index or a film thickness; a non-glare layer or an antiglare layer (both having an antiglare function); a near infrared-absorbing layer formed by a compound or a metal absorbing a near infrared light; a layer having a color regulating function for absorbing a visible light of a specified wavelength region; an antistain layer enabling easy removal of a stain such as finger prints; a hard coat layer not easily scratched; a layer having an impact absorbing function; or a layer capable of avoiding glass scattering in case of a glass breakage. Such functional layer may be provided on a side opposite to the emulsion layer across the substrate, or on a same side.

Such functional layer may be adhered directly on a PDP, or may be adhered on a transparent substrate such as a glass plate or an acrylic resin plate, separate from the plasma display panel. Such functional film is called an optical filter (or simply a filter).

An antireflective layer with an antireflective function can be formed, in order to avoid a reduction in the contrast by suppressing a reflection of an external light, by a method of laminating an inorganic substance such as a metal oxide, a fluoride, a silicide, a boride, a carbide, a nitride, or a sulfide in a single layer or in plural layers by a vacuum evaporation, a sputtering, an ion plating or an ion beam assisted method, or a method of laminating resins of different refractive indexes such as an acrylic resin and a fluorinated resin in a single layer or in plural layer.

Also it is possible to adhere a film subjected to such antireflective treatment on a filter. Also a non-glare layer or an antiglare layer may be provided if necessary. The non-glare layer or the antiglare layer can be prepared by a method of preparing an ink with a fine powder such as silica, melamine resin or acrylic resin and coating such ink on the surface. In such case, the ink can be cured by light or heat. Also it is possible to adhere a film, subjected to a non-glare or antiglare treatment, onto the filter. Also a hard coat layer may be provided if necessary.

A near infrared absorbing layer can be, more specifically, a layer containing a near infrared absorbing dye such as a metal complex, or a silver sputtered layer. Also the silver sputtered layer, by sputtering a dielectric layer and a metal layer alternately on the substrate, can cut off a near infrared light, a far infrared light and a light of a wavelength of 1000 nm or longer, from a far infrared light to an electromagnetic wave. The dielectric layer contains a transparent metal oxide such as indium oxide or zinc oxide as the dielectric material. Also the metal layer generally contains silver or a silver-palladium alloy. Such silver sputtered layer generally has a laminated structure or 3, 5, 7 or 11 layers starting from a dielectric layer.

In PDP, since a blue light-emitting phosphor has characteristics of slightly emitting a red light in addition to the blue light, there is encountered a drawback that a portion to be displayed in blue color is displayed in a purplish color. The aforementioned layer having a color regulating function for absorbing a visible light of a specified wavelength region is used for correcting the color of the emitted light as a countermeasure and contains a dye capable of absorbing a light in the vicinity of 595 nm.

A translucent electromagnetic shield film obtained by the producing method of the invention, having a satisfactory electromagnetic shield property and a light transmitting property, can also be utilized as a translucent electromagnetic shield material. It can also be utilized as various conductive wiring materials such as a circuit wiring. In particular, the translucent electromagnetic shield film of the invention can be advantageously employed as a translucent electromagnetic shield film for use on a front face of a display such as a cathode ray tube (CRT), a plasma display panel (PDP), a liquid crystal display panel, or an electroluminescence (EL), a microwave oven, an electronic appliance or a printed circuit board, particularly a translucent electromagnetic shield film for a plasma display panel.

As explained in the foregoing, the translucent electromagnetic shield of the invention can be advantageously utilized as a translucent electromagnetic shield film for a plasma display panel. Therefore, a plasma display panel prepared with the translucent electromagnetic shield film for the plasma display panel, including a translucent electromagnetic shield film of the invention has a high electromagnetic shielding ability, a high contrast and a high luminocity and can be prepared with a low cost.

In the following, the present invention will be clarified further by examples. In the following examples, a material, an amount of use, a proportion, a content of processing and a processing procedure may be suitably varied within the scope of the invention. Therefore the scope of the invention should not be construed restrictively by such examples.

### Example 1

### Preparation of Samples

A polyethylene terephthalate (PET) substrate was coated, in succession from the side of the substrate, with an undercoat layer, an antihalation layer, an emulsion layer and a protective layer. Also a backing layer was coated on a side of the substrate opposite to the emulsion layer, thereby obtaining a sample. In the following, a method of preparation of a coating liquid and a coating amount will be explained for each layer.

### (Formation of Undercoat Layer)

An undercoat layer was formed by coating a coating liquid containing gelatin by 50 mg/m² and lithium silicate by 150 mg/m².

### (Formation of Antihalation Layer)

An antihalation layer was formed by coating a coating liquid containing gelatin by 1 g/m² and a following compound AH-1 by 150 mg/m².

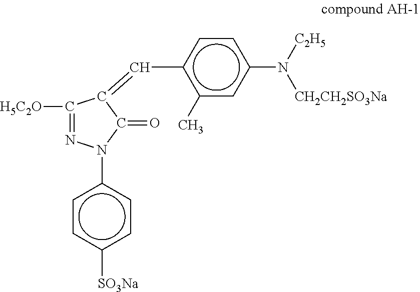

### (Emulsion Layer)

An emulsion was prepared in the following manner, corresponding to an emulsion layer of each sample.

### * Preparation of Emulsion A

There was prepared an emulsion A containing 7.5 g of gelatin to 60 g of Ag in an aqueous medium and containing silver iodobromide grains, having a sphere-corresponding average diameter of 0.05 μm and constituted of silver iodide by 2 mol. % and silver bromide by 98 mol. %. There were employed an Ag/gelatin volume ratio of 1/0.6 and gelatin species formed by a mixture of a low-molecular gelatin of an average molecular weight of 20,000, a high-molecular gelatin of an average molecular weight of 100,000, and an oxidation-processed gelatin of an average molecular weight of 100,000. In the emulsion A, K₃Rh₂Br₉ and K₂IrCl₆ were added to dope the silver bromide grains with Rh ions and Ir ions. Also in the emulsion A, Na₂PdCl₄ was added and a gold-sulfur sensitization was executed with chloroauric acid and sodium thiosulfate.

Then, in the emulsion A, there were added a following compound A-1 as a sensitizing dye; following compounds A-2, A-3, A-4 and A-5 as irradiation preventing agents; 1,2-bis(vinylsulfonylacetamide)ethan as a hardening agent; 4-hydroxy-6-methyl-1,3,3a,7-tetrazaindene as a stabilizer; 1-phenyl-5-mercaptotetrazole as an antifoggant; a following compound A-6 as a surfactant; and a following compound A-7 as a viscosifier. Then the emulsion A was so coated on the antihalation layer as to obtain a silver coating amount of 3 g/m² (sample A).

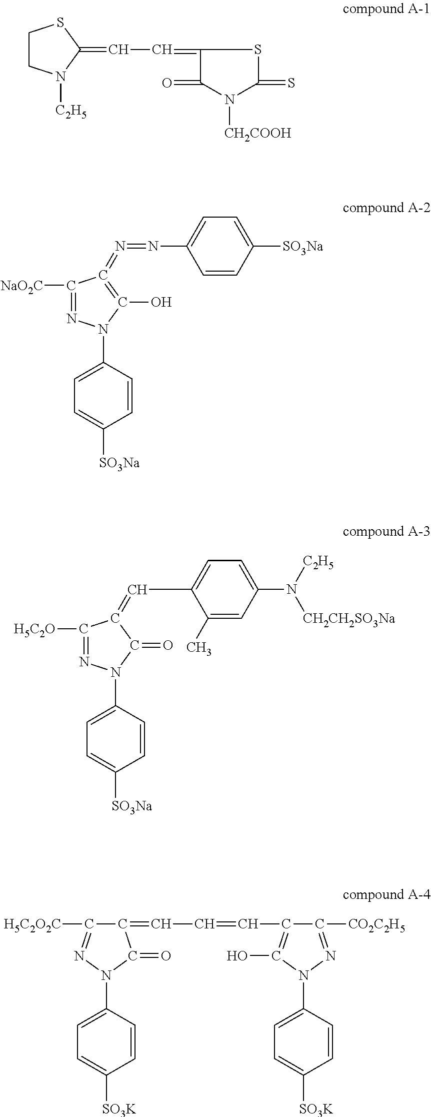

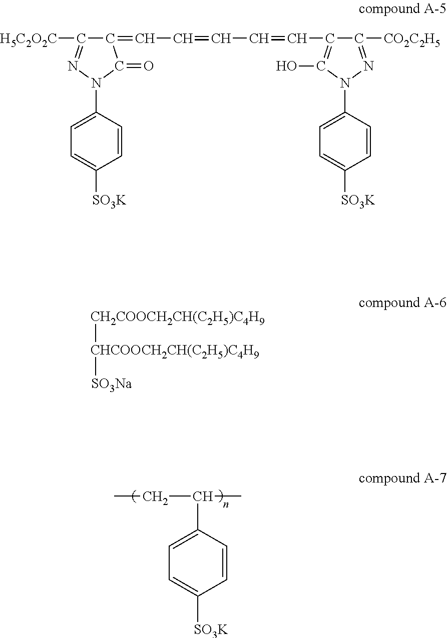

### * Preparation of Emulsion B

There was prepared, by a double jet method, an emulsion B containing 7.5 g of gelatin to 60 g of Ag in an aqueous medium and containing mono-dispersion cubic silver chlorobromide grains, having a sphere-corresponding average diameter of 0.2 μm and constituted of silver bromide by 30 mol. % and silver chloride by 70 mol. %. There were employed an Ag/gelatin volume ratio of 1/0.6 and gelatin species formed by a mixture of a low-molecular gelatin of an average molecular weight of 20,000, a high-molecular gelatin of an average molecular weight of 100,000, and an oxidation-processed gelatin of an average molecular weight of 100,000. In the emulsion B, 2×10⁻⁶ g of potassium hexabromorhodic acid and 3×10⁻⁵ g of potassium hexachloroiridate were added to dope the silver chlorobromide grains with Rh ions and Ir ions. Also in the emulsion B, Na₂PdCl₄ was added and a gold-sulfur sensitization was executed with chloroauric acid and sodium thiosulfate.

Then, in the emulsion B, there were added a following compound B-1 as a sensitizing dye; a following compound B-2 as an irradiation preventing agents; 1,3-divnylsulfonyl-2-propanol as a hardening agent; 4-hydroxy-6-methyl-1,3,3a,7-tetrazaindene and hydroquinone as stabilizers; 1-phenyl-5-mercaptotetrazole as an antifoggant; and colloidal silica. Then the emulsion B was so coated on the antihalation layer as to obtain a silver coating amount of 5 g/m² (sample B).

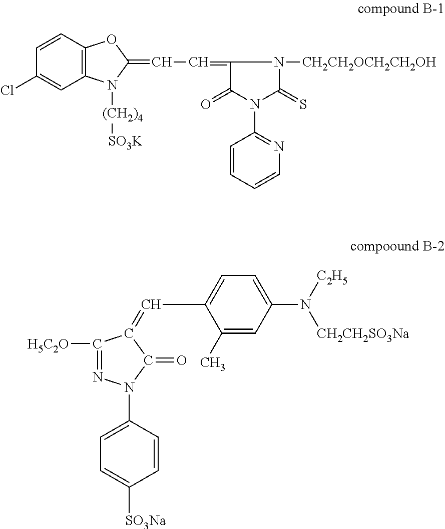

### * Preparation of Emulsion C

A cubic silver chloroiodobromide emulsion C having an average grain size of 0.23 μm and containing silver chloride by 70 mol. % was prepared in the following manner. There were employed an Ag/gelatin volume ratio of 1/0.6 and gelatin species formed by a mixture of a low-molecular gelatin of an average molecular weight of 20,000, a high-molecular gelatin of an average molecular weight of 100,000, and an oxidation-processed gelatin of an average molecular weight of 100,000.

Solutions 1-5 were prepared by mixing following compositions:

### (Composition of Solution 1)

| | | |
|---|---|---|
| water | 1 | liter |
| gelatin | 10 | g |
| sodium chloride | 2.0 | g |
| 1,3-dimethylimidazolidine-2-thione | 20 | mg |
| sodium benzenethiosulfonate | 8 | mg |

### (Composition of Solution 2)

| | | |
|---|---|---|
| water | 400 | ml |
| silver nitrate | 100 | g |

### (Composition of Solution 3)

| | | |
|---|---|---|
| water | 400 | ml |
| sodium chloride | 27.1 | g |
| potassium bromide | 21.0 | g |
| ammonium hexachloroiridate (III) | 20 | ml |
| (0.001% aqueous solution) | | |
| potassium hexachlororhodate (III) | 7 | ml |
| (0.001% aqueous solution) | | |

### (Composition of Solution 4)

| | | |
|---|---|---|
| water | 400 | ml |
| silver nitrate | 100 | g |

### (Composition of Solution 5)

| | | |
|---|---|---|
| water | 400 | ml |
| sodium chloride | 27.1 | g |
| potassium bromide | 21.0 | g |

In the solution 1 maintained at 40° C. and pH 4.5, the solutions 2 and 3 were simultaneously added under agitation, over 15 minutes, to form nucleus grains. Subsequently the solutions 4 and 5 were added over 15 minutes. After the addition, 0.15 g of potassium iodide were added to complete the grain formation.

Then, according to an ordinary flocculation method, the obtained grains were washed with water and gelatin was added. Then the mixture was regulated at pH of 5.7 and pAg of 7.5, there were added 1.0 mg of sodium thiosulfate, 4.0 mg of chloroauric acid, 1.5 mg of triphenylphosphine selenide, 8 mg of sodium benzenethiosulfonate and 2 mg of sodium benzenethiosulfinate to execute a chemical sensitization at 55° C. to obtain an optimum sensitivity. Then 100 mg of 4-hydroxy-6-methyl-1,3,3a,7-tetrazaindene as a stabilizer and phenoxyethanol as an antiseptic to obtain a cubic silver chloroiodobromide emulsion C of an average grain size of 0.23 μm, containing silver chloride by 70 mol. %.

The emulsion C was subjected to a spectral sensitization by adding a following sensitizing dye C(i) by 2.0×10⁻⁴ mol/mol·Ag and a following sensitizing dye C(ii) by 7.0×10⁻⁴ mol/mol·Ag. Then there were added KBr by 3.4×10⁻⁴ mol/mol·Ag, a following compound C-1 by 5.0×10⁻⁴ mol/mol·Ag, a following compound C-2 by 8.0×10⁻⁴ mol/mol·Ag, hydroquinone by 1.2×10⁻² mol/mol·Ag, a following compound C-3 by 1.8×10⁻⁴ mol/mol·Ag, a following compound C-4 by 3.5×10⁻⁴ mol/mol·Ag, a polyethyl acrylate latex in an amount of 30 mass % to gelatin, colloidal silica of a particle size of 10 mμ in an amount of 15 mass % to gelatin, and a following compound C-5 in an amount of 4 mass % to gelatin, and the obtained emulsion C was so coated on the substrate as to obtain a silver coating amount of 5 g/m².

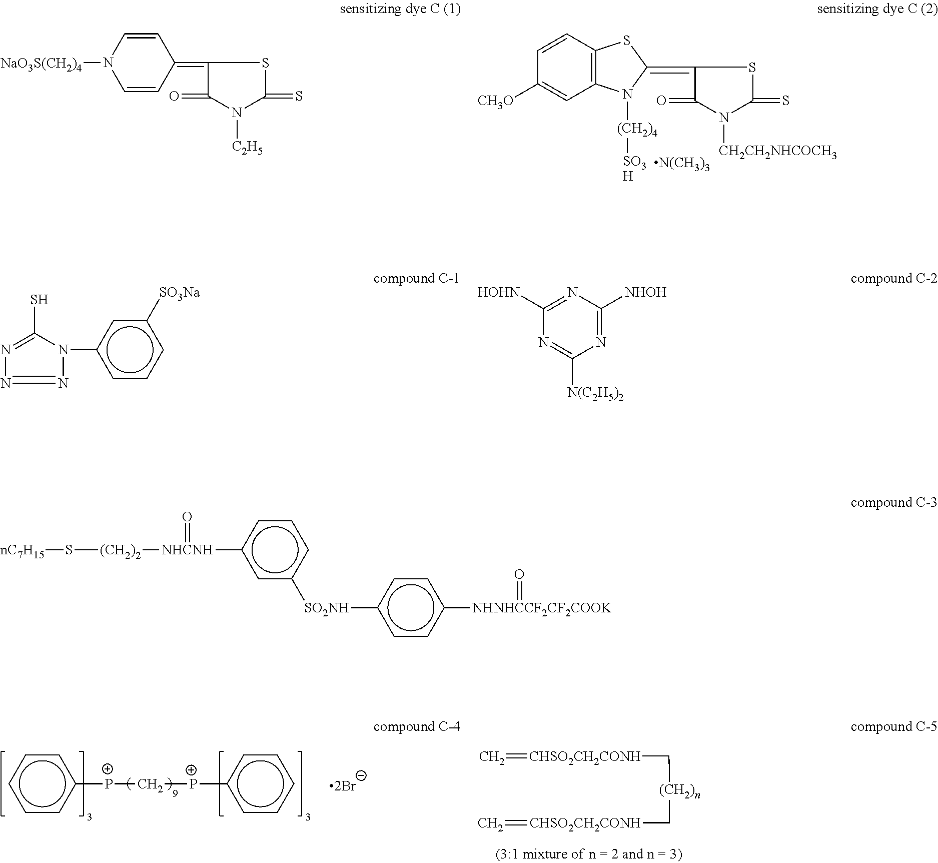

### * Preparation of Emulsion D

Cubic silver chloride emulsions Da, Db having an average grain size of 0.16 μm were prepared in the following manner. There were employed an Ag/gelatin volume ratio of 1/0.6 and gelatin species formed by a mixture of a low-molecular gelatin of an average molecular weight of 20,000, a high-molecular gelatin of an average molecular weight of 100,000, and an oxidation-processed gelatin of an average molecular weight of 100,000.

### Preparation of Emulsion Da

In a 1.5% aqueous gelatin solution of pH=2.0 maintained at 40° C. and containing sodium chloride, sodium benzenethiosulfonate in an amount of 3×10⁻⁵ moles per 1 mole of silver, and 4-hydroxy-6-methyl-1,3,3a,7-tetrazaindene by 5×10⁻³ moles, an aqueous solution of silver nitrate and an aqueous solution of sodium chloride containing K₂[Ru(NO)Cl₅] in an amount of 5×10⁻⁵ moles per 1 mole of silver were simultaneously added by a double jet method over 3 minutes and seconds at a potential of 95 mV, by such an amount corresponding to a half of silver in the final grains, thereby regulating core grains to an average grain size of 0.12 μm. Then the aqueous solution of silver nitrate and the aqueous solution of sodium chloride containing K₂[Ru(NO)Cl₅] in an amount of 5×10⁻⁵ moles per 1 mole of silver were added in the same manner as above over 7 minutes to obtain cubic silver chloride grains of an average grain size of 0.16 μm (variation factor 12%).

Then the grains were washed with water in a flocculation method known in the art to eliminate soluble salts, and, after an addition of gelatin and an addition of a compound D-1 and phenoxyethanol as antiseptics in an amount each of 60 mg per 1 mole of silver, the mixture was adjusted to pH of 5.1 and pAg of 7.5. Then sodium thiosulfate by 1×10⁻⁵ moles per 1 mole of silver, a selenium sensitizer SE-4 by 1×10⁻⁵ moles and chloroauric acid by 4×10⁻⁵ moles were added, and a chemical sensitization was executed by heating at 60° C. for 60 minutes. Then 4-hydroxy-6-methyl-1,3,3a,7-tetrazaindene as a stabilizer was added by 2×10⁻³ moles per 1 mole of silver, and pH value was regulated to 5.7 (final grains having pH=5.7, pAg=7.5 and Ru=5×10⁻⁵ mol/mol·Ag.

### Preparation of Emulsion Db

An emulsion Db was prepared in the same manner as the emulsion Da, except that an amount of addition of K₂[Ru(NO)Cl₅] was changed to 3×10⁻⁵ mol/mol·A.

Following compounds were added to each of the emulsions Da and Db, and silver halide emulsion layers were coated in superposed layers on a substrate in such a manner that the emulsion Da constitutes an upper emulsion layer and the emulsion Db constitutes a lower emulsion layer. The coating was so conducted that the coated silver layer in the upper/lower layers was 2.8/2.3 g/m².

Emulsion Layer Coating Liquids (Coating Amount of Each Compound being a Sum in the Upper and Lower Emulsion Layer)

| 1-phenyl-5-mercaptotetrazole | 10 | mg/m² |
|---|---|---|
| sodium 3-(5-mercaptotetrazole) | 11 | mg/m² |
| benzenesulfonate | | |
| sodium N-oleyl-N-methyltaurine | 19 | mg/m² |
| compound D-2 | 20 | mg/m² |
| compound D-3 | 20 | mg/m² |
| compound D-4 | 13 | mg/m² |
| compound D-5 | 15 | mg/m² |
| compound D-6 | 70 | mg/m² |
| ascorbic acid | 1 | mg/m² |
| acetic acid | an amount to obtain a | |
| | film pH of 5.2-6.0 | |
| compound D-7 | 1 | g/m² |
| Ribolan-1400 | 50 | mg/m² |

| | |
|---|---|
| (manufactured by Lion Oils and Fats Co.) | |
| compound D-8 | an amount to obtain a swell rate in |
| | water of 80% (pH regulated at 5.6) |

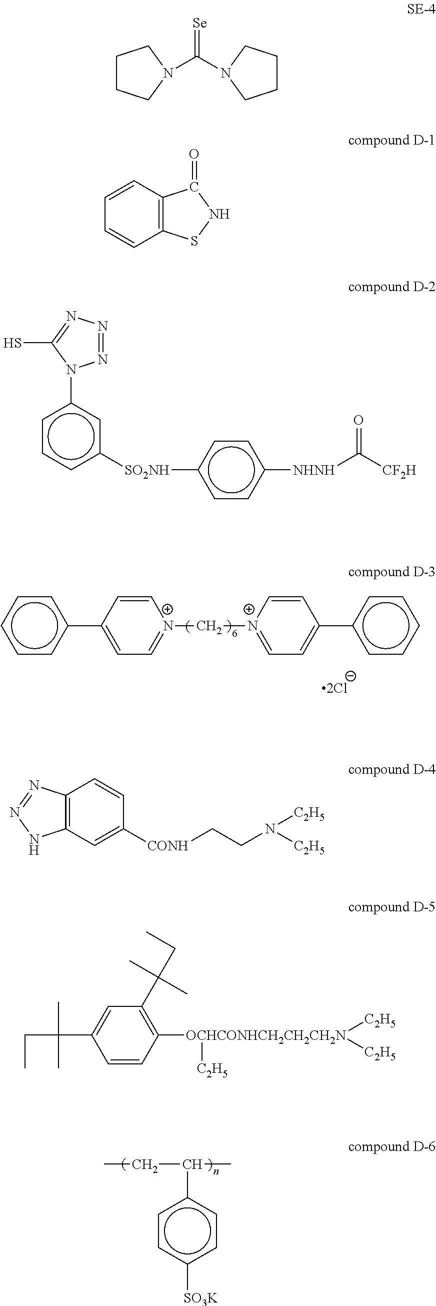

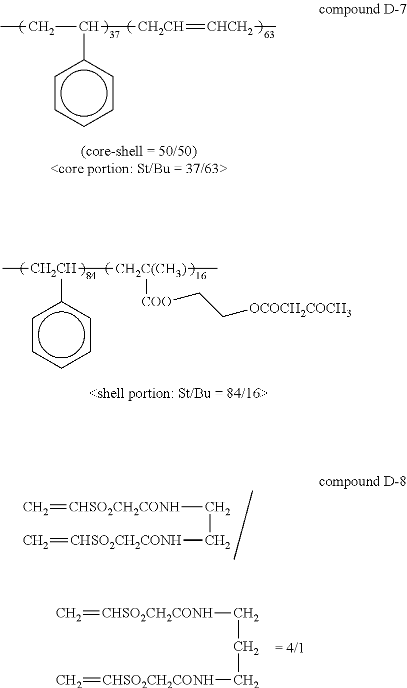

### * Preparation of Emulsion E

A cubic silver chloroiodobromide emulsion E having an average grain size of 0.22 μm containing silver chloride by 70 mol % was prepared in the following manner. There were employed an Ag/gelatin volume ratio of 1/0.6 and gelatin species formed by a mixture of a low-molecular gelatin of an average molecular weight of 20,000, a high-molecular gelatin of an average molecular weight of 100,000, and an oxidation-processed gelatin of an average molecular weight of 100,000.

Solutions 1-5 were prepared by mixing following compositions:

### (Composition of Solution 1)

| | | |
|---|---|---|
| water | 1 | liter |
| gelatin | 10 | g |
| sodium chloride | 1.5 | g |
| 1,3-dimethylimidazolidine-2-thione | 20 | mg |
| sodium benzenethiosulfonate | 8 | mg |

### (Composition of Solution 2)

| | | |
|---|---|---|
| water | 400 | ml |
| silver nitrate | 100 | g |

### (Composition of Solution 3)

| | | |
|---|---|---|
| water | 400 | ml |
| sodium chloride | 27.1 | g |
| potassium bromide | 21.0 | g |
| ammonium hexachloroiridate (III) | 20 | ml |
| (0.001% aqueous solution) | | |
| potassium hexachlororhodate (III) | 60 | ml |
| (0.001% aqueous solution) | | |

### (Composition of Solution 4)

| | | |
|---|---|---|
| water | 400 | ml |
| silver nitrate | 100 | g |

### (Composition of Solution 5)

| | | |
|---|---|---|
| water | 400 | ml |
| sodium chloride | 27.1 | g |
| potassium bromide | 21.0 | g |

In the solution 1 maintained at 37° C. and pH 4.5, the solutions 2 and 3 were simultaneously added under agitation, over 15 minutes, to form nucleus grains. Subsequently the solutions 4 and 5 were added over 15 minutes. After the addition, 0.15 g of potassium iodide were added to complete the grain formation.

Then, according to an ordinary flocculation method, the obtained grains were washed with water and gelatin was added. Then the mixture was regulated at pH of 5.7 and pAg of 7.5, there were added 1.0 mg of sodium thiosulfate, 4.0 mg of chloroauric acid, 1.5 mg of triphenylphosphine selenide, 8 mg of sodium benzenethiosulfonate and 2 mg of sodium benzenethiosulfinate to execute a chemical sensitization at 55° C. to obtain an optimum sensitivity. Then 100 mg of 4-hydroxy-6-methyl-1,3,3a,7-tetrazaindene as a stabilizer and phenoxyethanol as an antiseptic to obtain a cubic silver chloroiodobromide emulsion E of an average grain size of 0.22 μm, containing silver chloride by 70 mol. %.

The emulsion E was subjected to a spectral sensitization by adding a following sensitizing dye E(i) by 6 mg/m² and a following sensitizing dye E(ii) by 10 mg/m². Then there were added KBr by 17 mg/m², a following compound E-1 by 2 mg/m², a following compound E-2 by 1 mg/m², a following compound E-3 by 5 mg/m², hydroquinone by 100 mg/m², sodium dodecylbenzenesulfonate by 8 mg/m², potassium polystyrenesulfonate by 80 mg/m², a polyethyl acrylate dispersion by 40 mg/m², a following compound E-4 by 7 mg/m², an acrylamide derivative represented by a formula E-5 by 1 mg/m², a following compound E-6 by 20 mg/m², 1,5-dihydroxy-2-benzaldoxime by 42 mg/m, and 1,3-divinylsulfonyl-2-propanol as a hardening agent by 200 mg/m², and the obtained emulsion was so coated on the substrate as to obtain a silver coating amount of 5 g/m².

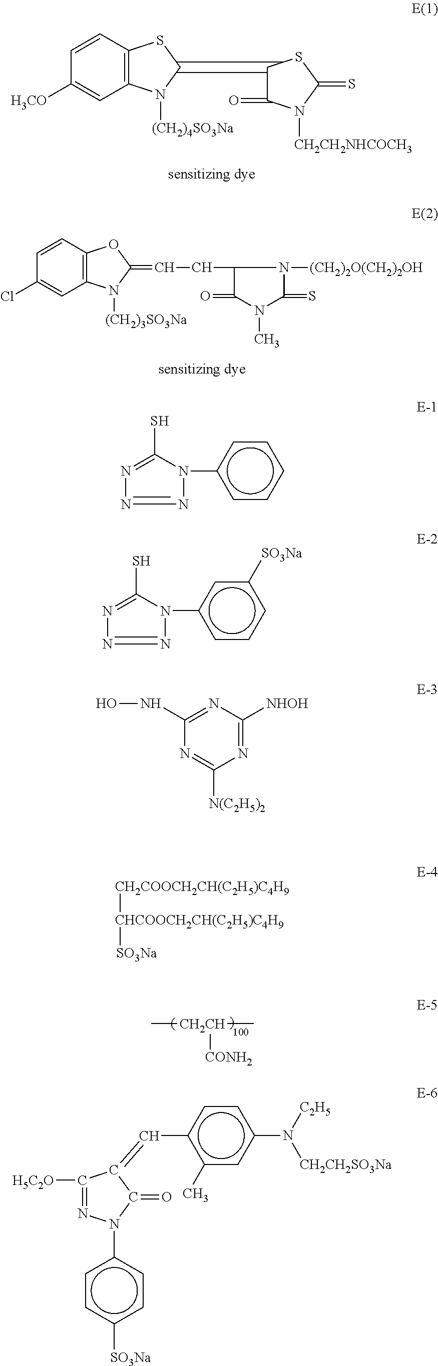

(Protective Layer)

A protective layer was formed on the emulsion layer in the following manner.

Following components were coated with following coating amounts: gelatin by 0.3 mg/m², dimethyl polysiloxane by 0.6 mg/m², 1.5-dihydroxy-2-benzaldoxime by 7 mg/m², amorphous silica matting agent of an average particle size of about 3.5 by 70 mg/m², a fluorinated surfactant represented by a following formula PC-1 by 5 mg/m², and a following compound PC-2 by 40 mg/m².

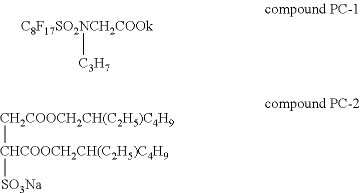

(Backing Layer)

A backing liquid was prepared with a following composition and coated with a coating amount of 15 ml/m² on a side opposite to the emulsion layer across the substrate.

[Composition]

| | | |
|---|---|---|
| binder (following compound BC-1) | 30 | g |
| dye (following compound BC-2) | 5 | g |
| dye (following compound BC-3) | 5 | g |
| dye (following compound BC-4) | 6 | g |
| dye (following compound BC-5) | 1.2 | g |
| ethanol | 420 | ml |
| methanol | 550 | ml |

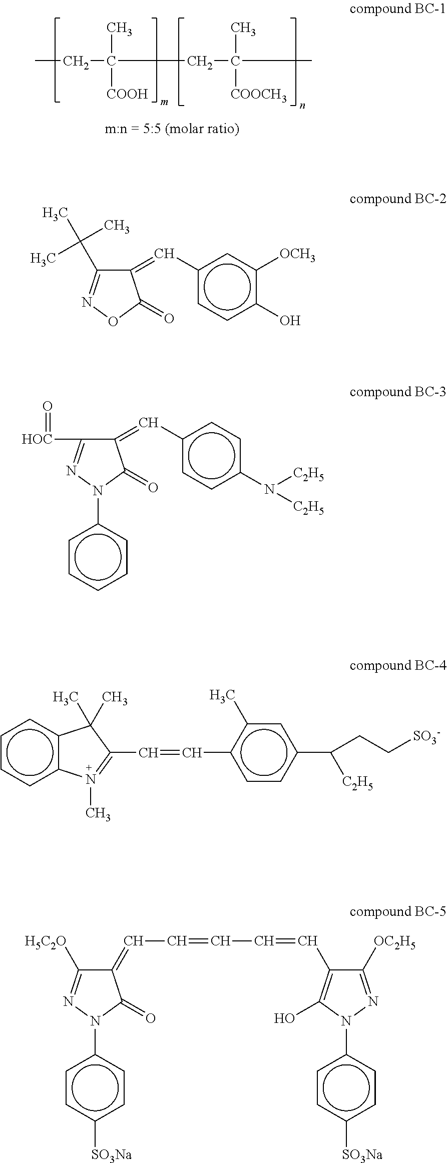

(Exposure/Development Process)

### <Preparation of Processing Chemical>

Formulations of a developing solution and a fixing solution for processing the samples are shown in the following.

(Developing Solution-1)

| | | |
|---|---|---|
| hydroquinone | 5 | g |
| N-methylo-p-aminophenyl ½ sulfate salt | 1 | g |
| anhydrous sodium sulfite | 50 | g |
| potassium hydroxide | 20 | g |
| potassium bromide | 0.5 | g |

Water was added to the composition to make 1 liter, and pH was adjusted to 11.2 with potassium hydroxide.

(Developing Solution-2)

| | | |
|---|---|---|
| hydroquinone | 20 | g |
| potassium sulfite | 5 | g |
| sodium ethylenediamine tetraacetate | 1 | g |
| potassium carbonate | 35 | g |
| sodium carbonate | 15 | g |
| potassium bromide | 3 | g |
| 5-nitroindazole | 4 | mg |
| triethylene glycol | 30 | g |
| diethanolamine | 20 | g |
| formaline-sodium bisulfite addition production | 50 | g |
| polyethylene glycol | 0.2 | g |
| (average molecular weight: 1,500) | | |

Water was added to the composition to make 1 liter, and pH was adjusted to 10.2 with sodium hydroxide.

(Developing Solution-3)

| | | |
|---|---|---|
| potassium hydroxide | 35 | g |
| diethylenetriamine-pentaacetic acid | 2 | g |
| sodium metabisulfite | 40 | g |
| potassium carbonate | 40 | g |
| potassium bromide | 3 | g |
| 5-methylbenzotriazole | 0.08 | g |
| 2,3,5,6,7,8-hexahydro-2-thioxo-4-(1 H)-quinazolinone | 0.04 | g |
| sodium 2-mercaptobenzoimidazole-5-sulfonate | 0.15 | g |
| hydroquinone | 25 | g |
| 4-hydroxymethyl-4-methyl-1-phenyl-3-pyrrazolidone | 0.45 | g |
| sodium erysorbate | 3 | g |
| diethylene glycol | 20 | g |

Water was added to the composition to make 1 liter, and pH was adjusted to 10.45 with potassium hydroxide.

(Fixing Solution)

| | | |
|---|---|---|
| ammonium thiosulfate | 359 | g |
| disodium ethylenediamine tetraacetate dihydrate | 0.09 | g |
| sodium thiosulfate pentahydrate | 32.8 | g |
| sodium sulfite | 64.8 | g |
| sodium hydroxide | 38.2 | g |
| glacial acetic acid | 87.3 | g |
| tartaric acid | 8.76 | g |
| sodium gluconate | 6.6 | g |
| aluminum sulfate | 25.3 | g |

Water was added to the composition to make 3 liter, and pH was adjusted to 4.85 with sulfuric acid or potassium hydroxide.

A coated film was exposed with a parallel light beam utilizing a high-pressure mercury lamp through a lattice-shaped photomask capable of providing a developed silver image of line/space=5 μm/195 μm (photomask having a lattice-shaped spaces with line/space=5 μm/195 μm (pitch 200 μm), then subjected to a development process by a development with the aforementioned developing solution and a processing with a fixing solution (N3X-R for CN16, manufactured by Fuji Photo Film Co.), or the aforementioned fixing solution, and rinsed with purified water.

(Plating Process)

An electroless copper plating was executed at 35° C. with a copper plating solution (electroless Cu plating solution of pH=12.5, containing copper sulfate by 0.06 mol/L, formalin by 0.22 mol/L, triethanolamine by 0.12 mol/L, polyethylene glycol by 100 ppm, potassium ferrocyanate by 50 ppm and α,α′-bipyridine by 20 ppm) and an oxidation process was conducted with an aqueous solution containing Fe(III) ions by 10 ppm, to obtain samples A and B of the invention.

Also for the purpose of comparison with a prior technology with a highest conductivity and a high light transmitting property, a metal mesh (comparative sample A) described in JP-A No. 10-41682, as a representative of the “(3) etched mesh formed by photolithography” described in the related background art.

The comparative sample A was prepared by a following procedure, according to Example 1 of JP-A No. 10-41682. At first, on a transparent PET film of a thickness of 50 an electrolytic copper foil was adhered by a heat lamination under conditions of 180° C. and 30 kgf/cm², utilizing an epoxy adhesion sheet (Nikaflex SAF, manufactured by Nikkan Kogyo Co.). In this operation, a rough surface of the electrolytic copper foil was positioned at the side of the epoxy adhesion sheet. The obtained PET film with the copper foil was subjected to a photolithographic process (adhesion of resist film, exposure, development, chemical etching and peeling of resist film) utilizing a photomask of a pitch of 200 μm same as in Examples 1 and 2, thereby forming a mesh pattern.

(Evaluation)

On each obtained sample having a conductive metal portion and a light transmitting portion, a line width of the conductive metal portion was measured to determine an aperture rate, and a surface resistivity was measured.

Also in order to judge whether the mesh of thin metal lines constitutes a hindrance in the observation of a displayed image, a following evaluation was conducted.

(Evaluation of Moiré Pattern)

An electromagnetic shield film was provided at a bias angle with a minimum moiré pattern in front of a Hitachi PDP and a Matsushita PDP, and a functional evaluation was made by a visual observation. The observation was made from a front direction of PDP and also from various viewing points in oblique directions to the image display plane of the PDP. A sample in which the moiré pattern was not visible in any observation was evaluated as “+”, and a sample in which a moiré pattern was observed was evaluated as “−”.

(Observation of Shape of Crossing Point of Mesh Lines)

A shape of a crossing point of fine metal lines constituting the mesh was observed and photographed under an optical microscope and a scanning electron microscope. A case where a line broadening in the crossing point was not significant, namely in case a line width at a crossing point was less than 1.5 times of a line width in a line portion, was rated as “+”, and a case where a line width at a crossing point was 1.5 times or more was rated as “−”.

(Color of Metal Portion)

A color of a metal portion of a mesh was visually evaluated, as black color was rated as “+” and brown color was rated as “−”.

Results of evaluation are shown, together with those of Comparative Example, in Table 1.

The sample A was prepared with the emulsion A, and the sample B was prepared with the emulsion B.

TABLE 1

| | line | aperture | surface | | line | metal | |
|---|---|---|---|---|---|---|---|
| | width | rate | resistivity | moiré | broadening | portion | |
| | (μm) | (%) | (Ω/sq) | pattern | at crossing | color | remarks |
| sample A | 12 | 88 | 0.06 | + | + | + | invention |
| sample B | 9 | 91 | 0.1 | + | + | + | invention |
| comparative A | 12 | 86 | 0.06 | − | − | − | comparative |
| (JP-A-10-41682) | | | | | | | (etching method) |

A comparison of the translucent conductive film of the comparative sample A and the samples of the present invention in Table 1 indicates that they are comparable in the aperture rate and the surface resistivity, thus having a light transmitting property and a conductivity (electromagnetic shielding ability) of a similar level. However, in the image quality (moiré pattern) of the PDP image, the comparative sample A showed a moiré pattern while the samples of the invention did not show such moiré pattern. Also while the comparative sample A showed a brown colored metal portion, the samples of the invention had a black color and was superior in the contrast of the displayed image.

Also in the observation of the shape of the crossing point of the mesh, the comparative sample A formed by an etching of a copper foil had a shape in which the crossing point was broader than the linear portion, while the samples of the invention did not show such broadening of the crossing point. The presence or absence of the moiré pattern is estimated to arise from the difference in the shape of the crossing points.

### Example 2

A silver salt diffusion transfer method for “conductive silver formation utilizing silver salt” described in the related background art and utilizing a silver deposition on a physical development nucleus (for example cf. JP-A No. 2000-149773 and WO01/51276) was compared with the samples of the invention, in the following manner.

On a hydrophilized transparent TAC (triacetyl cellulose) substrate, a physical development nucleus layer and a photosensitive layer were coated, and the sample was then subjected to an exposure through a mesh-shaped photomask of a pitch of 200 μm and a development by a DTR method. Then it was subjected to an electroless silver plating process and an electrolytic Cu plating to obtain a comparative sample C. Also a sample C of the invention was prepared in the same manner as in Example 1, utilizing an emulsion C.

Both the sample C of the invention and the comparative sample C had a mesh shape of a line width of 12 μm, a pitch of 200 μm and an aperture rate of 88%.

Results of measurements on the transmittance of the light transmitting portion and the surface resistivity on these samples, in the same manner as explained above, are shown in Table 2.

TABLE 2

| | | transmit- | remarks | |
|---|---|---|---|---|
| | | tance | presence/absence | |
| | surface | of light | of physical | |
| | resistivity | transmitting | development | |
| | (Ω/sq) | portion | nucleus | note |
| sample A of | 0.06 | 99 | absent | invention |
| invention | | | | |
| comparative | 0.08 | 75 | present | comparative |
| sample C | | | | |

Table 2 indicates that the translucent electromagnetic shield film of the invention (sample C) has a comparable conductivity and an excellent light transmitting property in comparison with the conductive metal film obtained by the silver salt diffusion transfer method utilizing physical development nuclei.

Also in the transparency of the light transmitting portion, the prior method utilizing the silver formation by the silver salt diffusion transfer method and the electroless silver plating (comparative sample C) is difficult to obtain a sufficiently transparent electromagnetic shield film suitable for use in front of a display, while the method of the invention not utilizing the coating of physical development nuclei can provide a shield film of a high transparency, thus being suitable for use in a display.

### Example 3

Samples D and E were prepared with emulsions D and E, in the same manner as in Example 1. Comparative samples An-En were prepared in the same manner as the samples A-E of the invention except that the protective layer was not coated at the preparation of the photosensitive material. These samples were evaluated in the same manner as in Example 1. Also an unevenness in the mesh was evaluated by visual observation under a white transmitting light. The samples of the invention did not show unevenness, while the comparative samples showed unevenness.

TABLE 3

| Sample | developer used | unevenness | remarks |
|---|---|---|---|
| comparative sample An | developer 2 | present | comparative |
| invention sample A | developer 2 | absent | invention |
| comparative sample Bn | developer 1 | present | comparative |
| invention sample B | developer 1 | absent | invention |
| comparative sample Cn | developer 1 | present | comparative |
| invention sample C | developer 1 | absent | invention |
| comparative sample Dn | developer 3 | present | comparative |
| invention sample D | developer 3 | absent | invention |

### Example 4

### (1) Preparation of Photosensitive Silver Halide Emulsion

There was prepared a photosensitive silver halide emulsion containing 4.6 g of gelatin to 60 g of Ag in an aqueous medium and containing silver chlorobromide grains, having a sphere-corresponding average diameter of 0.09 μm. There were employed an Ag/gelatin volume ratio of 1/0.6 and gelatin species formed by a mixture of a low-molecular gelatin of an average molecular weight of 20,000, a high-molecular gelatin of an average molecular weight of 100,000, and an oxidation-processed gelatin of an average molecular weight of 100,000.

In the photosensitive silver halide emulsion, K₃Rh₂Br₉ and K₂IrCl₆ were added to dope the silver chlorobromide grains with Rh ions and Ir ions. Also in the photosensitive silver halide emulsion, Na₂PdCl₄ was added and a gold-sulfur sensitization was executed with chloroauric acid and sodium thiosulfate.

### (2) Preparation of Silver Halide Photosensitive Material

The photosensitive silver halide emulsion was coated, together with a gelatin hardening agent, on polyethylene terephthalate (PET) so as to obtain a silver coating amount of 15 g/m². The PET was subjected to a hydrophilic treatment prior to the coating.

### (3) Conductive Silver Material

The silver halide photosensitive material was uniformly exposed with a high-pressure mercury lamp, and subjected to a chemical development process with a development with a following developing solution-4 and a processing with a fixing solution (N3X-R for CN16, manufactured by Fuji Photo Film Co.). It was then rinsed with purified water to obtain a conductive silver material.

(Developing Solution-4)

1 liter of the developing solution contains following compounds:

| | | |
|---|---|---|
| hydroquinone | 0.037 | mol/L |
| N-methylaminophenol | 0.016 | mol/L |
| sodium metaborate | 0.140 | mol/L |
| sodium hydroxide | 0.360 | mol/L |
| sodium bromide | 0.031 | mol/L |
| potassium metabisulfite | 0.187 | mol/L |

A thickness of an obtained silver film was measured with a thickness measuring instrument, and an electrical resistance was measured with a low resistivity meter to obtain a volume resistivity, which was identified as 50 μΩcm.

### Example 5

A conductive silver material having a PET substrate was obtained in the same manner as in Example 4 except that the development was conducted with a following developing solution.

Across section of the PET film having the obtained silver film was observed under an optical microscope and a scanning electron microscope (SEM) to determine a thickness of the prepared silver film. Also an electrical resistance was measured with a low resistivity meter to obtain a volume resistivity, which was identified as 8 μΩcm.

(Developing Solution-5)

| | | |
|---|---|---|
| hydroquinone | 15 | g |
| sodium sulfite | 3 | g |
| ethylenediamine tetraacetic acid | 2 | g |
| potassium carbonate | 50 | g |
| potassium bromide | 3 | g |
| formalin-sodium bisulfite addition product | 60 | g |
| polyethylene glycol (average molecular weight: 2000) | 1 | g |

Water was added to the composition to make 1 liter, and pH was adjusted to 10.2 with sodium hydroxide.

Then a conductive silver material was prepared in the same manner as described above except that the exposure was executed with a parallel light beam from a high-pressure mercury lamp, utilizing a striped photomask with line/space=8 μm/8 μm. It was a silver film formed on the PET substrate having a striped pattern with line/space=8 μm/8 μm and a volume resistivity thereof was 8 μΩcm.

As explained in the foregoing, the present invention allows to easily obtain a fine line pattern required for an electrode or a wiring material, having a high conductivity, and the obtained silver pattern can be utilized advantageously as an electrode or a wiring material.

What is claimed is:

1. A conductive silver material containing a conductive metallic silver image having a volume resistivity of 1.6 to 100 μΩcm, wherein the conductive metallic silver image is produced by:
coating a photosensitive silver halide emulsion including at least a silver halide on a substrate to form a silver salt containing layer, and
subjecting the silver salt containing layer to exposure and chemical development.

2. The conductive silver material according to claim 1, wherein the chemical development is conducted by treating the silver salt containing layer with a developing solution containing a sulfite in an amount of 0.20 mol/liter or higher.

3. The conductive silver material according to claim 1, wherein the chemical development is conducted by treating the silver salt containing layer with a developing solution containing a sulfite in an amount of 0.30 to 1.2 mol/liter.

4. The conductive silver material according to claim 2, wherein the sulfite is selected from the group consisting of sodium sulfite, potassium sulfite, lithium sulfite, ammonium sulfite, sodium bisulfite, potassium metabisulfite, or sodium formaldehyde bisulfite.

5. The conductive silver material according to claim 2, wherein the developing solution further contains an ascorbic acid derivative.

6. The conductive silver material according to claim 1, wherein the chemical development is followed by fixing with a fixing solution containing sodium thiosulfate or ammonium thiosulfate.

7. The conductive silver material according to claim 6, wherein the fixing agent contains a fixing agent in an amount of 0.1 to 2 mol/liter.

8. The conductive silver material according to claim 1, wherein the photosensitive silver halide emulsion has an Ag/binder volume ratio of at least 1/1.

9. The conductive silver material according to claim 1, wherein the metallic silver image is further subjected to physical development and/or plating process.
